(19) United States
(12) Patent Application Publication
(10) Pub. No.: US 2024/0145560 A1
(43) Pub. Date: May 2, 2024

(54) SEMICONDUCTOR DEVICE

(71) Applicant: SAMSUNG ELECTRONICS CO., LTD., Suwon-si (KR)

(72) Inventors: Dong Hoon HWANG, Suwon-si (KR); Myung Il KANG, Suwon-si (KR); Do Young CHOI, Suwon-si (KR)

(21) Appl. No.: 18/211,786

(22) Filed: Jun. 20, 2023

(30) Foreign Application Priority Data
Nov. 1, 2022 (KR) 10-2022-0143716

(51) Int. Cl. H01L 29/417; H01L 29/06; H01L 29/423; H01L 29/66; H01L 29/775; H01L 29/786

(52) U.S. Cl. CPC H01L 29/41775; H01L 29/0673; H01L 29/41733; H01L 29/42392; H01L 29/66545; H01L 29/775; H01L 29/78696

(57) ABSTRACT

A semiconductor device includes an active pattern on a substrate extending in a first horizontal direction, a gate electrode on the active pattern extending in a second horizontal direction, a source/drain region on the active pattern, an upper source/drain region apart from the lower source/drain region, a lower source/drain between upper and lower source/drain regions and connected to the lower source/drain region, an upper source/drain connected to an upper source/drain region, an interlayer insulating layer surrounding the upper source/drain region, a through-via on opposing sidewalls in the second horizontal direction extending through the interlayer insulating layer in the vertical direction, the through-via being spaced from the upper source/drain region and upper source/drain contact in the second horizontal direction, the through-via being connected to the lower source/drain contact, and a dam structure on each of the opposing sidewalls in the horizontal direction of the upper source/drain region.

### CROSS-REFERENCE TO RELATED APPLICATION

This application claims priority from Korean Patent Application No. 10-2022-0143716 filed on Nov. 1, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor device. More specifically, the present disclosure relates to a semiconductor device including an MBCFET™ (Multi-Bridge Channel Field Effect Transistor).

### 2. Description of Related Art

One of scaling schemes for increasing an integration density of an integrated circuit device is to employ a multi-gate transistor in which a silicon body in a shape of a fin or a nanowire is formed on a substrate, and a gate is formed on a surface of the silicon body.

### SUMMARY

A purpose of the present disclosure is to provide a semiconductor device having a structure in which an upper channel region is stacked on a lower channel region, in which a dam structure is disposed between a through-via connected to a lower source/drain contact and an upper source/drain region, thereby preventing a short-circuit from occurring between the through-via and the upper source/drain region.

According to some embodiments, there is provided a semiconductor device, including a substrate, an active pattern disposed on the substrate and extending in a first horizontal direction, a gate electrode disposed on the active pattern and extending in a second horizontal direction different from the first horizontal direction, a lower source/drain region disposed on the active pattern and on at least one side of the gate electrode, an upper source/drain region spaced apart from the lower source/drain region in a vertical direction, a lower source/drain contact disposed between the lower source/drain region and the upper source/drain region, and connected to the lower source/drain region, an upper source/drain contact disposed on the upper source/drain region and connected to the upper source/drain region, an interlayer insulating layer surrounding the upper source/drain region, a through-via disposed on one of both opposing sidewalls in the second horizontal direction of the upper source/drain region and extending through the interlayer insulating layer in the vertical direction, the through-via is spaced apart from each of the upper source/drain region and the upper source/drain contact in the second horizontal direction, the through-via is connected to the lower source/drain contact, and a dam structure disposed on each of the both opposing sidewalls in the second horizontal direction of the upper source/drain region, the dam structure is in contact with the upper source/drain region, the dam structure is spaced apart from the through-via in the second horizontal direction.

According to some embodiments of the present disclosure, there is provided a semiconductor device, including a substrate, an active pattern disposed on the substrate and extending in a first horizontal direction, a gate electrode disposed on the active pattern and extending in a second horizontal direction different from the first horizontal direction, a lower source/drain region disposed on the active pattern and on at least one side of the gate electrode, an upper source/drain region spaced apart from the lower source/drain region in a vertical direction, a lower source/drain contact disposed between the lower source/drain region and the upper source/drain region, and connected to the lower source/drain region, a through-via spaced apart from the upper source/drain region in the second horizontal direction, and connected to the lower source/drain contact, and a dam structure disposed on each of both opposing sidewalls in the second horizontal direction of the upper source/drain region, the dam structure is in contact with the upper source/drain region, the dam structure is spaced apart from the through-via in the second horizontal direction, the dam structure overlaps the lower source/drain contact in the vertical direction, wherein the dam structure includes a first portion in contact with a first sidewall of the upper source/drain region, and a second portion in contact with a second sidewall of the upper source/drain region opposite to the first sidewall of the upper source/drain region in the second horizontal direction, the second portion is spaced apart from the first portion in the second horizontal direction.

According to some embodiments of the present disclosure, there is provided a semiconductor device, including a substrate, an active pattern disposed on the substrate and extending in a first horizontal direction, a plurality of lower nanosheets stacked on the active pattern to be spaced apart from each other in a vertical direction, an isolation layer disposed on the plurality of lower nanosheets, a plurality of upper nanosheets stacked on the isolation layer to be spaced apart from each other in the vertical direction, a gate electrode disposed on the active pattern and extending in a second horizontal direction different from the first horizontal direction, the gate electrode surrounds each of the plurality of lower nanosheets, the isolation layer and the plurality of upper nanosheets, a lower source/drain region disposed on the active pattern and on at least one side of each of the plurality of lower nanosheets, an upper source/drain region disposed on the lower source/drain region and on at least one side of each of the plurality of upper nanosheets, a lower source/drain contact disposed between the lower source/drain region and the upper source/drain region, and connected to the lower source/drain region, an upper source/drain contact disposed on the upper source/drain region and connected to the upper source/drain region, an interlayer insulating layer surrounding the upper source/drain region, a through-via disposed on one of both opposing sidewalls in the second horizontal direction of the upper source/drain region and extending through the interlayer insulating layer in the vertical direction, the through-via is spaced apart from each of the upper source/drain region and the upper source/drain contact in the second horizontal direction, the through-via is connected to the lower source/drain contact, and a dam structure disposed on each of both opposing sidewalls in the second horizontal direction of the upper source/drain region, the dam structure is in contact with each of the upper source/drain region and the upper source/drain contact, the dam structure is spaced apart from the through-via in the second horizontal direction, the dam structure overlaps the lower source/drain contact in the vertical direction, wherein the dam structure includes a first portion in contact with a first sidewall of the upper source/drain region, and a second portion in contact with a second sidewall of the upper source/drain region opposite to the first sidewall of the upper source/drain region in the second horizontal direction, the second portion is spaced apart from the first portion in the second horizontal direction.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

### BRIEF DESCRIPTION OF DRAWINGS

Features will become apparent to those of skill in the art by describing in detail exemplary embodiments with reference to the attached drawings in which:

FIG. 1 is a schematic layout diagram for illustrating a semiconductor device according to some embodiments of the present disclosure;

FIG. 2 is a layout diagram to illustrate a lower structure of the semiconductor device as shown in FIG. 1;

FIG. 3 is a layout diagram to illustrate an upper structure of the semiconductor device as shown in FIG. 1;

FIG. 4 is a cross-sectional view taken along a line A-A′ of each of FIGS. 1 to 3;

FIG. 5 is a cross-sectional view taken along a line B-B′ of each of FIGS. 1 to 3;

FIG. 6 is a cross-sectional view taken along a line C-C′ of each of FIGS. 1 to 3;

FIGS. 7 to 42 are diagrams of intermediate structures corresponding to intermediate steps for illustrating a method of manufacturing a semiconductor device according to some embodiments of the present disclosure;

FIG. 43 is a cross-sectional view for illustrating a semiconductor device according to some further embodiments of the present disclosure;

FIG. 44 is a cross-sectional view for illustrating a semiconductor device according to some still further embodiments of the present disclosure;

FIG. 45 is a cross-sectional view for illustrating a semiconductor device according to some still yet further embodiments of the present disclosure; and

FIG. 46 to FIG. 48 are cross-sectional views for illustrating a semiconductor device according to some still yet further embodiments of the present disclosure.

### DETAILED DESCRIPTION

In the drawings of the semiconductor device according to some embodiments as described below, an example in which the semiconductor device includes a transistor (MBCFET™ (Multi-Bridge Channel Field Effect Transistor) including a nanosheet or a fin-type transistor (FinFET) including a fin-like pattern-shaped channel region is described. In some implementations, the semiconductor device may include a tunneling transistor (FET) or a three-dimensional (3D) transistor. In still another example, the semiconductor device according to some embodiments may include a bipolar junction transistor or a lateral double diffusion transistor (LDMOS).

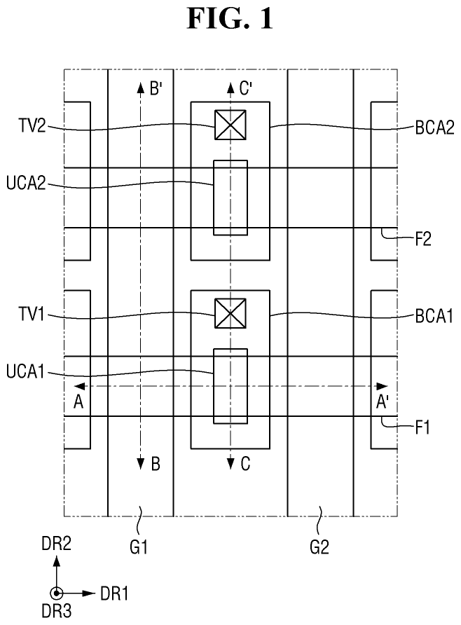

Hereinafter, a semiconductor device according to some embodiments of the present disclosure will be described with reference to FIG. 1 to FIG. 6.

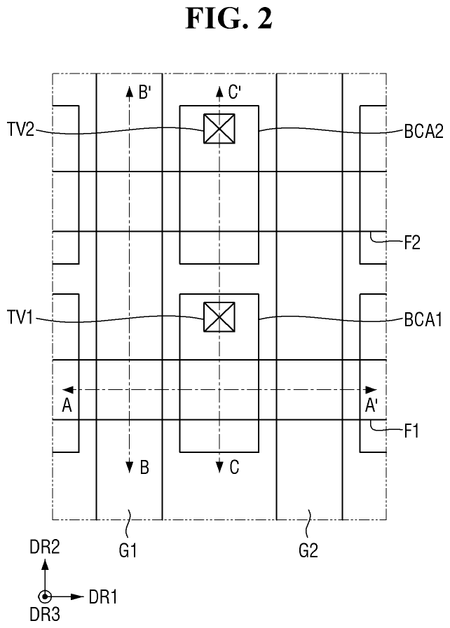

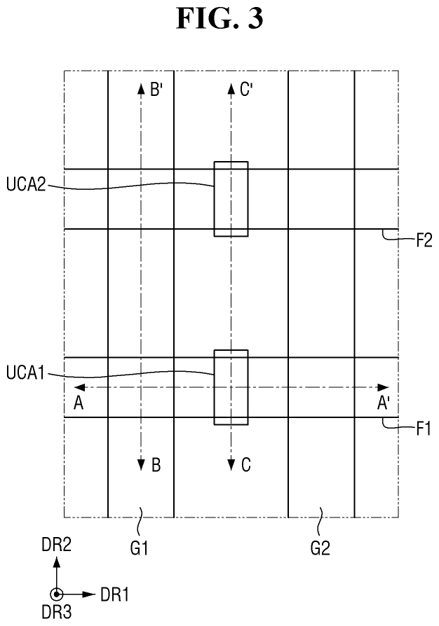

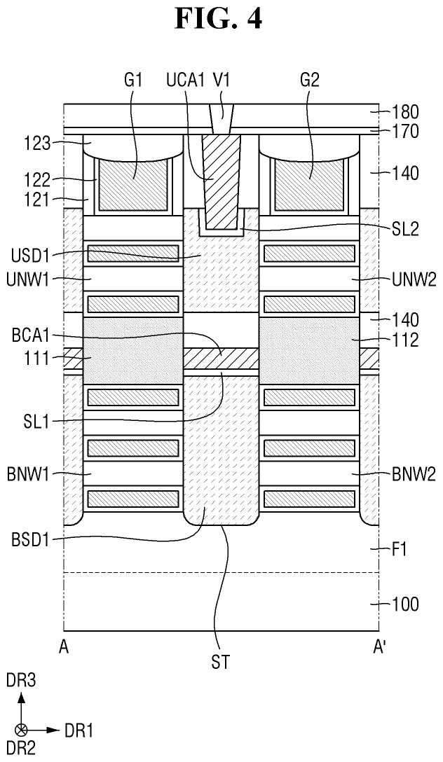

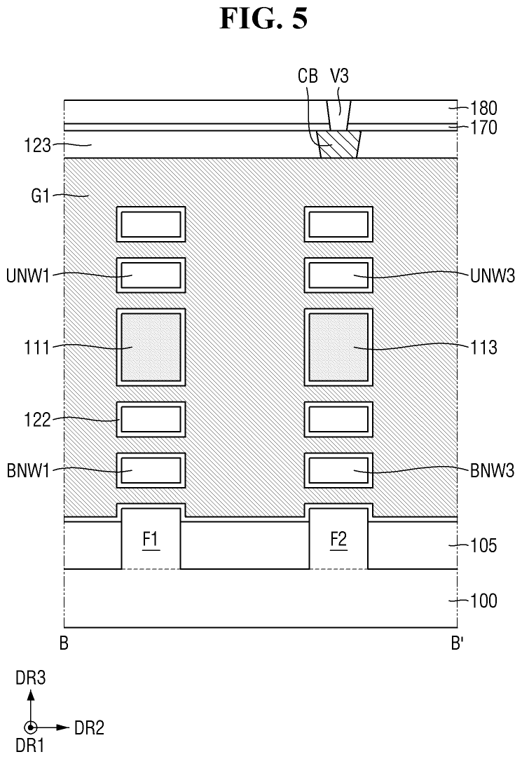

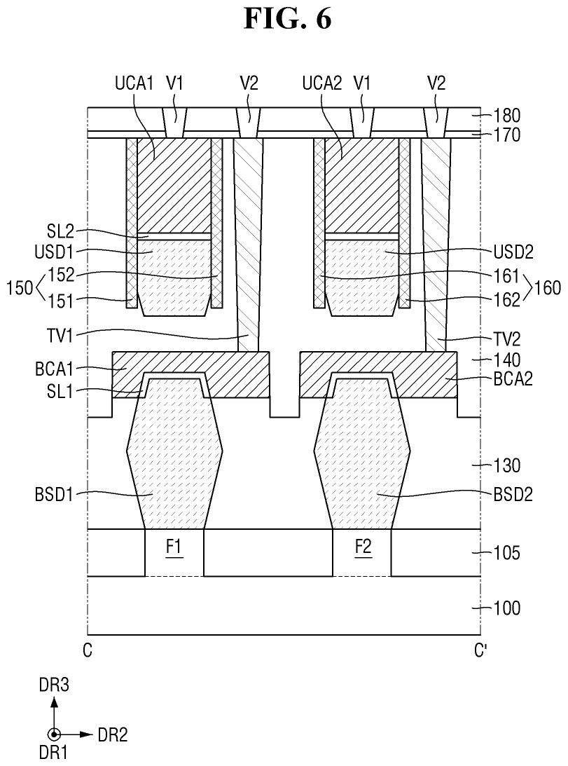

FIG. 1 is a schematic layout diagram that illustrates a semiconductor device according to some embodiments. FIG. 2 is a layout diagram to illustrate a lower structure of the semiconductor device as shown in FIG. 1. FIG. 3 is a layout diagram to illustrate an upper structure of the semiconductor device as shown in FIG. 1. FIG. 4 is a cross-sectional view taken along a line A-A′ of each of FIG. 1 to FIG. 3. FIG. 5 is a cross-sectional view taken along a line B-B′ of each of FIG. 1 to FIG. 3. FIG. 6 is a cross-sectional view taken along a line C-C′ of each of FIG. 1 to FIG. 3. Referring to FIG. 1 to FIG. 6, the semiconductor device according to some embodiments includes a substrate 100, first and second active patterns F1 and F2, a field insulating layer 105, first to third plurality of lower nanosheets BNW1, BNW2, and BNW3, first to third plurality of upper nanosheets UNW1, UNW2, and UNW3, first to third isolation layers 111, 112, and 113, first and second gate electrodes G1 and G2, a gate spacer 121, a gate insulating layer 122, a capping pattern 123, first and second lower source/drain regions BSD1 and BSD2, first and second upper source/drain regions USD1 and USD2, a first interlayer insulating layer 130, a second interlayer insulating layer 140, first and second lower source/drain contacts BCA1 and BCA2, first and second upper source/drain contacts UCA1 and UCA2, first and second silicide layers SL1 and SL2, first and second through-vias TV1 and TV2, a gate contact CB, a first dam structure 150, a second dam structure 160, an etch stop layer 170, a third interlayer insulating layer 180, and first to third vias V1, V2, and V3.

The substrate 100 may be embodied as a silicon substrate or an SOI (silicon-on-insulator). In some implementations, the substrate 100 may include silicon germanium, SGOI (silicon germanium on insulator), indium antimonide, a lead telluride compound, indium arsenide, indium phosphide, gallium arsenide or gallium antimonide, as non-limiting examples.

Hereinafter, each of a first horizontal direction DR1 and a second horizontal direction DR2 may be defined as a direction parallel to a top surface of the substrate 100. The second horizontal direction DR2 may be defined as a different direction from the first horizontal direction DR1. A vertical direction DR3 may be defined as a direction perpendicular to each of the first horizontal direction DR1 and the second horizontal direction DR2.

Each of the first active pattern F1 and the second active pattern F2 may protrude from the substrate 100 in the vertical direction DR3. Each of the first active pattern F1 and the second active pattern F2 may extend in the first horizontal direction DR1 while being disposed on the substrate 100. The second active pattern F2 may be spaced apart from the first active pattern F1 in the second horizontal direction DR2. Each of the first active pattern F1 and the second active pattern F2 may be a portion of the substrate 100 or may include an epitaxial layer grown from the substrate 100.

The field insulating layer 105 may be disposed on the substrate 100. The field insulating layer 105 may surround a sidewall of each of the first active pattern F1 and the second active pattern F2. For example, a top surface of each of the first active pattern F1 and the second active pattern F2 may protrude upwardly in the vertical direction DR3 beyond a top surface of the field insulating layer 105, as non-limiting examples. In some further embodiments, the top surface of each of the first active pattern F1 and the second active pattern F2 may be coplanar with the top surface of the field insulating layer 105.

The first plurality of lower nanosheets BNW1 may be disposed on the first active pattern F1. The first plurality of lower nanosheets BNW1 may include a plurality of nanosheets stacked on top of each other and spaced apart from each other in the vertical direction DR3 while being disposed on the first active pattern F1. The first plurality of lower nanosheets BNW1 may be disposed in a region where the first active pattern F1 and the first gate electrode G1 intersect each other.

The second plurality of lower nanosheets BNW2 may be disposed on the first active pattern F1. The second plurality of lower nanosheets BNW2 may include a plurality of nanosheets stacked on top of each other and spaced apart from each other in the vertical direction DR3 while being disposed on the first active pattern F1. The second plurality of lower nanosheets BNW2 may be spaced apart from the first plurality of lower nanosheets BNW1 in the first horizontal direction DR1. The second plurality of lower nanosheets BNW2 may be disposed in a region where the first active pattern F1 and the second gate electrode G2 intersect each other.

The third plurality of lower nanosheets BNW3 may be disposed on the second active pattern F2. The third plurality of lower nanosheets BNW3 may include a plurality of nanosheets stacked on top of each other and spaced apart from each other in the vertical direction DR3 while being disposed on the second active pattern F2. The third plurality of lower nanosheets BNW3 may be spaced apart from the first plurality of lower nanosheets BNW1 in the second horizontal direction DR2. The third plurality of lower nanosheets BNW3 may be disposed in a region where the second active pattern F2 and the first gate electrode G1 intersect each other.

Although not shown, a fourth plurality of lower nanosheets may be disposed on the second active pattern F2. The fourth plurality of lower nanosheets may include a plurality of nanosheets stacked on top of each other and spaced apart from each other in the vertical direction DR3 while being disposed on the second active pattern F2. The fourth plurality of lower nanosheets may be spaced apart from the third plurality of lower nanosheets BNW3 in the first horizontal direction DR1. The fourth plurality of lower nanosheets may be disposed in a region where the second active pattern F2 and the second gate electrode G2 intersect each other.

In FIG. 4 and FIG. 6, it is illustrated that each of the first to third plurality of lower nanosheets BNW1, BNW2, and BNW3 include two nanosheets stacked in the vertical direction DR3. However, this description is intended only for convenience of illustration. In some implementations, each of the first to third plurality of lower nanosheets BNW1, BNW2, and BNW3 may include three or more nanosheets stacked in the vertical direction DR3.

The first plurality of upper nanosheets UNW1 may be disposed on the first plurality of lower nanosheets BNW1. The first plurality of upper nanosheets UNW1 may include a plurality of nanosheets stacked on top of each other and spaced apart from each other in the vertical direction DR3 while being disposed on the first plurality of lower nanosheets BNW1. The first plurality of upper nanosheets UNW1 may be disposed in a region where the first active pattern F1 and the first gate electrode G1 intersect each other.

The second plurality of upper nanosheets UNW2 may be disposed on the second plurality of lower nanosheets BNW2. The second plurality of upper nanosheets UNW2 may include a plurality of nanosheets stacked on top of each other and spaced apart from each other in the vertical direction DR3 while being disposed on the second plurality of lower nanosheets BNW2. The second plurality of upper nanosheets UNW2 may be spaced apart from the first plurality of upper nanosheets UNW1 in the first horizontal direction DR1. The second plurality of upper nanosheets UNW2 may be disposed in a region where the first active pattern F1 and the second gate electrode G2 intersect each other.

The third plurality of upper nanosheets UNW3 may be disposed on the third plurality of lower nanosheets BNW3. The third plurality of upper nanosheets UNW3 may include a plurality of nanosheets stacked on top of each other and spaced apart from each other in the vertical direction DR3 while being disposed on the third plurality of lower nanosheets BNW1. The third plurality of upper nanosheets UNW3 may be spaced apart from the first plurality of upper nanosheets UNW1 in the second horizontal direction DR2. The third plurality of upper nanosheets UNW3 may be disposed in a region where the second active pattern F2 and the first gate electrode G1 intersect each other.

Although not shown, a fourth plurality of upper nanosheets may be disposed on the fourth plurality of lower nanosheets. The fourth plurality of upper nanosheets may include a plurality of nanosheets stacked on top of each other and spaced apart from each other in the vertical direction DR3 while being disposed on the fourth plurality of lower nanosheets. The fourth plurality of upper nanosheets may be spaced apart from the third plurality of upper nanosheets UNW3 in the first horizontal direction DR1. The fourth plurality of upper nanosheets may be disposed in a region where the second active pattern F2 and the second gate electrode G2 intersect each other.

FIG. 4 and FIG. 6 illustrate that each of the first to third plurality of upper nanosheets UNW1, UNW2, and UNW3 include two nanosheets stacked in the vertical direction DR3. However, this description is intended only for convenience of illustration. In some further embodiments, each of the first to third plurality of upper nanosheets UNW1, UNW2, and UNW3 may include three or more nanosheets stacked in the vertical direction DR3.

For example, each of the first to third plurality of lower nanosheets BNW1, BNW2, and BNW3, and each of the first to third plurality of upper nanosheets UNW1, UNW2, and UNW3 may include silicon (Si), as non-limiting examples. In some additional embodiments, each of the first to third plurality of lower nanosheets BNW1, BNW2, and BNW3, and each of the first to third plurality of upper nanosheets UNW1, UNW2, and UNW3 may include silicon germanium (SiGe).

The first isolation layer 111 may be disposed between the first plurality of lower nanosheets BNW1 and the first plurality of upper nanosheets UNW1. For example, the first isolation layer 111 may be spaced apart from each of the first plurality of lower nanosheets BNW1 and the first plurality of upper nanosheets UNW1 in the vertical direction DR3, as non-limiting examples. The second isolation layer 112 may be disposed between the second plurality of lower nanosheets BNW2 and the second plurality of upper nanosheets UNW2. For example, the second isolation layer 112 may be spaced apart from each of the second plurality of lower nanosheets BNW2 and the second plurality of upper nanosheets UNW2 in the vertical direction DR3, as non-limiting examples.

The third isolation layer 113 may be disposed between the third plurality of lower nanosheets BNW3 and the third plurality of upper nanosheets UNW3. For example, the third isolation layer 113 may be spaced apart from each of the third plurality of lower nanosheets BNW3 and the third plurality of upper nanosheets UNW3 in the vertical direction DR3, as non-limiting examples. Although not shown, a fourth isolation layer may be disposed between the fourth plurality of lower nanosheets and the fourth plurality of upper nanosheets. For example, the fourth isolation layer may be spaced apart from each of the fourth plurality of lower nanosheets and the fourth plurality of upper nanosheets in the vertical direction DR3, as non-limiting examples.

Each of the first to third isolation layers 111, 112, and 113 may include an insulating material. For example, each of the first to third isolation layers 111, 112, and 113 may include, for example, at least one of silicon nitride (SiN), silicon oxycarbonitride (SiOCN), silicon boron carbonitride (SiBCN), silicon carbonitride (SiCN), silicon oxynitride SiON or combinations thereof, as non-limiting examples.

The first gate electrode G1 may extend in the second horizontal direction DR2 while being disposed on the first active pattern F1, the second active pattern F2 and the field insulating layer 105. The first gate electrode G1 may surround each of the first plurality of lower nanosheets BNW1, the third plurality of lower nanosheets BNW3, the first isolation layer 111, the third isolation layer 113, the first plurality of upper nanosheets UNW1 and the third plurality of upper nanosheets UNW3. In some further embodiments, the first gate electrode G1 may be divided into a first lower gate electrode and a first upper gate electrode. In this case, the first lower gate electrode may surround some of the first plurality of lower nanosheets BNW1, some of the third plurality of lower nanosheets BNW3, a portion of the first isolation layer 111, and a portion of the third isolation layer 113. Further, the first upper gate electrode may surround the remainder of the first plurality of upper nanosheets UNW1, the remainder of the third plurality of upper nanosheets UNW3, the remainder of the first isolation layer 111, and the remainder of the third isolation layer 113.

The second gate electrode G2 may extend in the second horizontal direction DR2 while being disposed on the first active pattern F1, the second active pattern F2 and field insulating layer 105. The second gate electrode G2 may be spaced apart from the first gate electrode G1 in the first horizontal direction DR1. The second gate electrode G2 may surround each of the second plurality of lower nanosheets BNW2, the fourth plurality of lower nanosheet, the second isolation layer 112, the fourth isolation layer, the second plurality of upper nanosheets UNW2 and the fourth plurality of upper nanosheets, as non-limiting examples

In some additional embodiments, the second gate electrode G2 may be divided into a second lower gate electrode and a second upper gate electrode. In this case, the second lower gate electrode may surround some of the second plurality of lower nanosheets BNW2, some of the fourth plurality of lower nanosheets, a portion of the second isolation layer 112, and a portion of the fourth isolation layer. Further, the second upper gate electrode may surround the remainder of the second plurality of upper nanosheets UNW2, the remainder of the fourth plurality of upper nanosheet, the remainder of the second isolation layer 112, and the remainder of the fourth isolation layer.

Each of the first gate electrode G1 and the second gate electrode G2 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) and combinations thereof, as non-limiting examples.

The gate spacer 121 may extend in the second horizontal direction DR2 and along each of both opposing sidewalls of the first gate electrode G1 while being disposed on the topmost nanosheet of the first plurality of upper nanosheets UNW1, the topmost nanosheet of the third plurality of upper nanosheets UNW3, and the field insulating layer 105. Further, the gate spacer 121 may extend in the second horizontal direction DR2 and along each of both opposing sidewalls of the second gate electrode G2 while being disposed on the topmost nanosheet of the third plurality of upper nanosheets UNW3, the topmost nanosheet of the fourth plurality of upper nanosheets, and the field insulating layer 105.

The gate spacer 121 may include, for example, at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), or combinations thereof, as non-limiting examples.

A source/drain trench ST may be formed on at least one side of each of the first and second gate electrodes G1 and G2 while being defined on each of the first active pattern F1 and the second active pattern F2. For example, the source/drain trench ST may be formed between the first gate electrode G1 and the second gate electrode G2. The source/drain trench ST may extend into each of the first active pattern F1 and the second active pattern F2.

The first lower source/drain region BSD1 may be disposed inside the source/drain trench ST while being disposed on the first active pattern F1. The first lower source/drain region BSD1 may be disposed on at least one side of each of the first and second gate electrodes G1 and G2 while being disposed on the first active pattern F1. For example, the first lower source/drain region BSD1 may be disposed between the first gate electrode G1 and the second gate electrode G2 while being disposed on the first active pattern F1. The first lower source/drain region BSD1 may be in contact with each of the first plurality of lower nanosheets BNW1 and the second plurality of lower nanosheets BNW2. For example, the first lower source/drain region BSD1 may contact each of both opposing sidewalls in the first horizontal direction DR1 of each of the first isolation layer 111 and the second isolation layer 11, as non-limiting examples.

The second lower source/drain region BSD2 may be disposed inside the source/drain trench ST while being on the second active pattern F2. The second lower source/drain region BSD2 may be disposed on at least one side of each of the first and second gate electrodes G1 and G2 while being on the second active pattern F2. For example, the second lower source/drain region BSD2 may be disposed between the first gate electrode G1 and the second gate electrode G2 while being on the second active pattern F2. The second lower source/drain region BSD2 may be in contact with each of the second plurality of lower nanosheets BNW2 and the fourth plurality of lower nanosheet. Although not shown, for example, the second lower source/drain region BSD2 may contact each of both opposing sidewalls in the first horizontal direction DR1 of each of the third isolation layer 113 and the fourth isolation layer, as non-limiting examples.

The first upper source/drain region USD1 may be disposed on at least one side of each of the first and second gate electrodes G1 and G2 while being on the first lower source/drain region BSD1. For example, the first upper source/drain region USD1 may be disposed between the first gate electrode G1 and the second gate electrode G2 while being disposed on the first lower source/drain region BSD1. The first upper source/drain region USD1 may be spaced apart from the first lower source/drain region BSD1 in the vertical direction DR3. The first upper source/drain region USD1 may contact each of the first plurality of upper nanosheets UNW1 and the second plurality of upper nanosheets UNW2.

The second upper source/drain region USD2 may be disposed on at least one side of each of the first and second gate electrodes G1 and G2 while being on the second lower source/drain region BSD2. For example, the second upper source/drain region USD2 may be disposed between the first gate electrode G1 and the second gate electrode G2 while being on the second lower source/drain region BSD2. The second upper source/drain region USD2 may be spaced apart from the second lower source/drain region BSD2 in the vertical direction DR3. The second upper source/drain region USD2 may contact each of the third plurality of upper nanosheets UNW3 and the fourth plurality of upper nanosheets.

The gate insulating layer 122 may be disposed between each of the first and second gate electrodes G1 and G2 and the field insulating layer 105. The gate insulating layer 122 may be disposed between each of the first and second gate electrodes G1 and G2 and each of the first to fourth plurality of lower nanosheets BNW1, BNW2, and BNW3. The gate insulating layer 122 may be disposed between each of the first and second gate electrodes G1 and G2 and each of the first to fourth isolation layers 111, 112, and 113. The gate insulating layer 122 may be disposed between each of the first and second gate electrodes G1 and G2 and the first lower source/drain region BSD1. The gate insulating layer 122 may be disposed between each of the first and second gate electrodes G1 and G2 and the second lower source/drain region BSD2.

Further, the gate insulating layer 122 may be disposed between each of the first and second gate electrodes G1 and G2 and each of the first to fourth plurality of upper nanosheets UNW1, UNW2, and UNW3. The gate insulating layer 122 may be disposed between each of the first and second gate electrodes G1 and G2 and the first upper source/drain region USD1. The gate insulating layer 122 may be disposed between each of the first and second gate electrodes G1 and G2 and the second upper source/drain region USD2. The gate insulating layer 122 may be disposed between each of the first and second gate electrodes G1 and G2 and the gate spacer 121.

The gate insulating layer 122 may contact each of the first lower source/drain region BSD1, the second lower source/drain region BSD2, the first upper source/drain region USD1 and the second upper source/drain region USD2, as non-limiting examples. In some further embodiments, an inner spacer may be disposed between each of the first lower source/drain region BSD1 and the second lower source/drain region BSD2 and the gate insulating layer 122. Further, in some still further embodiments, an inner spacer may be disposed between each of the first upper source/drain region USD1 and the second upper source/drain region USD2 and the gate insulating layer 122.

The gate insulating layer 122 may include silicon oxide, silicon-germanium oxide, germanium oxide, silicon oxynitride, silicon nitride, or a high-k material having a higher dielectric constant than that of silicon oxide. The high dielectric constant (high-k) material may include at least one of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some further embodiments may include an NC (negative capacitance) FET using a negative capacitor. For example, the gate insulating layer 122 may include a ferroelectric material film having ferroelectric properties and a paraelectric material film having paraelectric properties.

The ferroelectric material film may have negative capacitance, and the paraelectric material film may have positive capacitance. For example, when two or more capacitors are connected in series to each other, and when capacitance of each of the capacitors has a positive value, a total capacitance becomes smaller than the capacitance of each individual capacitor. On the other hand, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this connection, in one example, the term ‘hafnium zirconium oxide’ may refer to a material obtained by doping hafnium oxide with zirconium (Zr). In another context, the term ‘hafnium zirconium oxide’ may refer to a compound of hafnium (Hf), zirconium (Zr), and oxygen (O).

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), and yttrium (Y).

When the dopant is aluminum (Al), the ferroelectric material film may contain about 3 to about 8 at % (atomic %) of aluminum. In this connection, a content of the dopant may be a content of aluminum based on a sum of hafnium and aluminum.

When the dopant is silicon (Si), the ferroelectric material film may contain about 2 to about 10 at % of silicon. When the dopant is yttrium (Y), the ferroelectric material film may contain about 2 to about 10 at % yttrium. When the dopant is gadolinium (Gd), the ferroelectric material film may contain about 1 to about 7 at % gadolinium. When the dopant is zirconium (Zr), the ferroelectric material film may contain about 50 to about 80 at % zirconium.

The paraelectric material film may have paraelectric properties. The paraelectric material film may include, for example, at least one of silicon oxide and metal oxide having a high dielectric constant. The metal oxide contained in the paraelectric material film may include, for example, at least one of hafnium oxide, zirconium oxide and aluminum oxide, as non-limiting examples.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film may be different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, the present disclosure is not limited thereto. Because a critical thickness exhibiting the ferroelectric properties may vary based on a type of the ferroelectric material, the thickness of the ferroelectric material film may vary depending on the type of the ferroelectric material.

In one example, the gate insulating layer 122 may include one ferroelectric material film. In another example, the gate insulating layer 122 may include a plurality of ferroelectric material films spaced apart from each other. In some implementations, the gate insulating layer 122 may have a stack film structure in which a plurality of ferroelectric material films and a plurality of paraelectric material films are alternately stacked on top of each other.

The capping pattern 123 may extend in the second horizontal direction DR2 while being disposed on each of the first and second gate electrodes G1 and G2. For example, the capping pattern 123 may contact each of a top surface of the gate spacer 121 and a top surface of the gate insulating layer 122, as non-limiting examples. In some further embodiments, the capping pattern 123 may be disposed between the gate spacers 121 while being on each of the first and second gate electrodes G1 and G2. The capping pattern 123 may include, for example, at least one of silicon nitride (SiN), silicon oxynitride (SiON), silicon oxide (SiO₂), silicon carbonitride (SiCN), silicon oxycarbonitride (SiOCN), or combinations thereof, as non-limiting examples.

The first interlayer insulating layer 130 may be disposed on the field insulating layer 105. The first interlayer insulating layer 130 may cover each of the first lower source/drain region BSD1 and the second lower source/drain region BSD2. The first interlayer insulating layer 130 may include, for example, at least one of silicon oxide, silicon nitride, silicon oxynitride, or a low dielectric constant (low-k) material. The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof, as non-limiting examples.

The second interlayer insulating layer 140 may be disposed on the first interlayer insulating layer 130. The second interlayer insulating layer 140 may cover each of both opposing sidewalls in the first horizontal direction DR1 of each of the first to fourth isolation layers 111, 112, and 113, the gate spacer 121, and the capping pattern 123. For example, a top surface of the second interlayer insulating layer 140 may be coplanar with a top surface of the capping pattern 123, as non-limiting examples. In some further embodiments, the second interlayer insulating layer 140 may cover the top surface of the capping pattern 123. The second interlayer insulating layer 140 may include, for example, at least one of silicon oxide, silicon nitride, silicon oxynitride, or a low-k material. For example, the second interlayer insulating layer 140 may include the same material as that of the first interlayer insulating layer 130, as non-limiting examples.

The first lower source/drain contact BCA1 may be disposed on at least one side of each of the first and second gate electrodes G1 and G2 while being disposed on the first lower source/drain region BSD1. For example, the first lower source/drain contact BCA1 may be disposed between the first gate electrode G1 and the second gate electrode G2 while being disposed on the first lower source/drain region BSD1. The first lower source/drain contact BCA1 may be disposed between the first lower source/drain region BSD1 and the first upper source/drain region USD1. The first lower source/drain contact BCA1 may extend in the second horizontal direction DR2. The first lower source/drain contact BCA1 may be connected to the first lower source/drain region BSD1. The first lower source/drain contact BCA1 may be spaced apart from the first upper source/drain region USD1.

Each of both opposing sidewalls in the first horizontal direction DR1 of the first lower source/drain contact BCA1 may contact each of the first isolation layer 111 and the second isolation layer 112. A bottom surface of the first lower source/drain contact BCA1 may be in contact with the first interlayer insulating layer 130. A top surface of the first lower source/drain contact BCA1 and each of both opposing sidewalls in the second horizontal direction DR2 of the first lower source/drain contact BCA1 may contact the second interlayer insulating layer 140. For example, each of both opposing sidewalls in the first horizontal direction DR1 of the first lower source/drain contact BCA1 does not contact the second interlayer insulating layer 140. Although not shown, the first lower source/drain contact BCA1 may contact the gate spacer 121 while being disposed on the field insulating layer 105.

The second lower source/drain contact BCA2 may be disposed on at least one side of each of the first and second gate electrodes G1 and G2 while being disposed on the second lower source/drain region BSD2. For example, the second lower source/drain contact BCA2 may be disposed between the first gate electrode G1 and the second gate electrode G2 while being disposed on the second lower source/drain region BSD2. The second lower source/drain contact BCA2 may be disposed between the second lower source/drain region BSD2 and the second upper source/drain region USD2. The second lower source/drain contact BCA2 may extend in the second horizontal direction DR2. The second lower source/drain contact BCA2 may be spaced apart from the first lower source/drain contact BCA1 in the second horizontal direction DR2. The second lower source/drain contact BCA2 may be connected to the second lower source/drain region BSD2. The second lower source/drain contact BCA2 may be spaced apart from the second upper source/drain region USD2 in the second horizontal direction DR2.

Although not shown, each of both opposing sidewalls in the first horizontal direction DR1 of the second lower source/drain contact BCA2 may contact each of the third isolation layer 113 and the fourth isolation layer. A bottom surface of the second lower source/drain contact BCA2 may be in contact with the first interlayer insulating layer 130. A top surface of the second lower source/drain contact BCA2 and each of both opposing sidewalls in the second horizontal direction DR2 of the second lower source/drain contact BCA2 may contact the second interlayer insulating layer 140. For example, each of both opposing sidewalls in the first horizontal direction DR1 of the second lower source/drain contact BCA2 does not contact the second interlayer insulating layer 140. Although not shown, the second lower source/drain contact BCA2 may contact the gate spacer 121 while being disposed on the field insulating layer 105.

For example, each of the first lower source/drain contact BCA1 and the second lower source/drain contact BCA2 may include a conductive material. In FIG. 4 and FIG. 6, each of the first lower source/drain contact BCA1 and the second lower source/drain contact BCA2 is illustrated to be formed as a single film. However, this illustration is intended only for convenience of illustration, and the present disclosure is not limited thereto. For example, each of the first lower source/drain contact BCA1 and the second lower source/drain contact BCA2 may be formed as a multilayer.

The first upper source/drain contact UCA1 may be disposed on at least one side of each of the first and second gate electrodes G1 and G2 while being disposed on the first upper source/drain region USD1. For example, the first upper source/drain contact UCA1 may be disposed between the first gate electrode G1 and the second gate electrode G2 while being disposed on the first upper source/drain region USD1. The first upper source/drain contact UCA1 may extend through the second interlayer insulating layer 140 in the vertical direction DR3 so as to be connected to the first upper source/drain region USD1.

For example, each of both opposing sidewalls in the second horizontal direction DR2 of the first upper source/drain contact UCA1 may contact the first dam structure 150. For example, each of both opposing sidewalls in the second horizontal direction DR2 of the first upper source/drain contact UCA1 may not contact the second interlayer insulating layer 140. For example, a width in the second horizontal direction DR2 of the first upper source/drain contact UCA1 may be equal to a width in the second horizontal direction DR2 of the first upper source/drain region USD1. For example, each of both opposing sidewalls in the second horizontal direction DR2 of the first upper source/drain contact UCA1 and each of both opposing sidewalls in the second horizontal direction DR2 of the first upper source/drain region USD1 may be aligned with each other in the vertical direction DR3.

The second upper source/drain contact UCA2 may be disposed on at least one side of each of the first and second gate electrodes G1 and G2 while being disposed on the second upper source/drain region USD2. For example, the second upper source/drain contact UCA2 may be disposed between the first gate electrode G1 and the second gate electrode G2 while being disposed on the second upper source/drain region USD2. The second upper source/drain contact UCA2 may extend through the second interlayer insulating layer 140 in the vertical direction DR3 so as to be connected to the second upper source/drain region USD2. The second upper source/drain contact UCA2 may be spaced apart from the first upper source/drain contact UCA1 in the second horizontal direction DR2.

For example, each of both opposing sidewalls in the second horizontal direction DR2 of the second upper source/drain contact UCA2 may contact the second dam structure 160, and each of both opposing sidewalls in the second horizontal direction DR2 of the second upper source/drain contact UCA2 may not contact the second interlayer insulating layer 140. For example, a width in the second horizontal direction DR2 of the second upper source/drain contact UCA2 may be equal to a width in the second horizontal direction DR2 of the second upper source/drain region USD2. For example, each of both opposing sidewalls in the second horizontal direction DR2 of the second upper source/drain contact UCA2 and each of both opposing sidewalls in the second horizontal direction DR2 of the second upper source/drain region USD2 may be aligned with each other in the vertical direction DR3.

For example, each of a top surface of the first upper source/drain contact UCA1 and a top surface of the second upper source/drain contact UCA2 may be coplanar with a top surface of the second interlayer insulating layer 140. For example, each of the first upper source/drain contact UCA1 and the second upper source/drain contact UCA2 may include a conductive material. FIG. 4 and FIG. 6 illustrate that each of the first upper source/drain contact UCA1 and the second upper source/drain contact UCA2 is formed as a single film. However, this illustration is intended only for convenience of illustration, as non-limiting examples. For example, each of the first upper source/drain contact UCA1 and the second upper source/drain contact UCA2 may be formed as a multilayer.

The first silicide layer SL1 may be disposed along and at a boundary surface between the first lower source/drain region BSD1 and the first lower source/drain contact BCA1. The first silicide layer SL1 may be disposed along and at a boundary surface between the second lower source/drain region BSD2 and the second lower source/drain contact BCA2. The second silicide layer SL2 may be disposed along and at a boundary surface between the first upper source/drain region USD1 and the first upper source/drain contact UCA1. The second silicide layer SL2 may be disposed along and at a boundary surface between the second upper source/drain region USD2 and the second upper source/drain contact UCA2. Each of the first silicide layer SL1 and the second silicide layer SL2 may include, for example, a metal silicide material.

For example, the gate contact CB may extend through the capping pattern 123 in the vertical direction DR3 so as to be connected to the first gate electrode G1. For example, a top surface of the gate contact CB may be coplanar with the top surface of the second interlayer insulating layer 140. For example, the top surface of the gate contact CB may be coplanar with each of the top surface of the first upper source/drain contact UCA1 and the top surface of the second upper source/drain contact UCA2. For example, the gate contact CB may include a conductive material. Although it is illustrated in FIG. 5 that the gate contact CB is formed as a single film, this illustration is intended only for convenience of illustration, and the present disclosure is not limited thereto. For example, the gate contact CB may be formed as a multilayer.

The first dam structure 150 may be disposed on each of both opposing sidewalls in the second horizontal direction DR2 of each of the first upper source/drain region USD1 and the first upper source/drain contact UCA1. The first dam structure 150 may extend in the vertical direction DR3 while being disposed inside the second interlayer insulating layer 140. For example, a bottom surface of the first dam structure 150 may be formed inside the second interlayer insulating layer 140. For example, a top surface of the first dam structure 150 may be coplanar with the top surface of the second interlayer insulating layer 140. For example, the top surface of the first dam structure 150 may be coplanar with the top surface of the first upper source/drain contact UCA1. The first dam structure 150 may overlap the first lower source/drain contact BCA1 in the vertical direction DR3. The first dam structure 150 may be spaced apart from the first lower source/drain contact BCA1 in the vertical direction DR3.

The first dam structure 150 may include a first portion 151 and a second portion 152. The first portion 151 of the first dam structure 150 may be disposed on a first sidewall of the first upper source/drain region USD1. The first portion 151 of the first dam structure 150 may be disposed on a first sidewall of the first upper source/drain contact UCA1. The first portion 151 of the first dam structure 150 may contact each of the first sidewall of the first upper source/drain region USD1 and the first sidewall of the first upper source/drain contact UCA1.

The second portion 152 of the first dam structure 150 may be disposed on a second sidewall of the first upper source/drain region USD1 opposite to the first sidewall of the first upper source/drain region USD1 in the second horizontal direction DR2. The second portion 152 of the first dam structure 150 may be disposed on a second sidewall of the first upper source/drain contact UCA1 opposite to the first sidewall of the first upper source/drain contact UCA1 in the second horizontal direction DR2. The second portion 152 of the first dam structure 150 may be spaced apart from the first portion 151 of the first dam structure 150 in the second horizontal direction DR2. The second portion 152 of the first dam structure 150 may contact each of the second sidewall of the first upper source/drain region USD1 and the second sidewall of the first upper source/drain contact UCA1.

For example, a thickness in the second horizontal direction DR2 of a portion of the first portion 151 of the first dam structure 150 in contact with the first upper source/drain region USD1 may be equal to a thickness in the second horizontal direction DR2 of a portion of the first portion 151 of the first dam structure 150 in contact with the first upper source/drain contact UCA1. For example, a thickness in the second horizontal direction DR2 of a portion of the second portion 152 of the first dam structure 150 in contact with the first upper source/drain region USD1 may be equal to as a thickness in the second horizontal direction DR2 of a portion of the first dam structure 150 in contact with the first upper source/drain contact UCA1.

The second dam structure 160 may be disposed on each of both opposing sidewalls in the second horizontal direction DR2 of each of the second upper source/drain region USD2 and the second upper source/drain contact UCA2. The second dam structure 160 may be spaced apart from the first dam structure 150 in the second horizontal direction DR2. The second dam structure 160 may include a first portion 161 and a second portion 162. The first portion 161 of the second dam structure 160 may be disposed on a first sidewall of each of the second upper source/drain region USD2 and the second upper source/drain contact UCA2. The second portion 162 of the second dam structure 160 may be disposed on a second sidewall of each of the second upper source/drain region USD2 and the second upper source/drain contact UCA2. The second dam structure 160 may have a structure similar to that of the first dam structure 150. Accordingly, further detailed description of the second dam structure 160 will not be repeated.

Each of the first dam structure 150 and the second dam structure 160 may include, for example, at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC) or combinations thereof.

The first through-via TV1 may extend through the second interlayer insulating layer 140 in the vertical direction DR3 so as to be connected to the first lower source/drain contact BCA1. The first through-via TV1 may be spaced apart from each of the first upper source/drain region USD1 and the first upper source/drain contact UCA1 in the second horizontal direction DR2. The first through-via TV1 may be spaced apart from the second portion 152 of the first dam structure 150 in the second horizontal direction DR2. For example, a top surface of the first through-via TV1 may be coplanar with each of the top surface of the second interlayer insulating layer 140, the top surface of the first dam structure 150 and the top surface of the first upper source/drain contact UCA1.

The second through-via TV2 may extend through the second interlayer insulating layer 140 in the vertical direction DR3 so as to be connected to the second lower source/drain contact BCA2. The second through-via TV2 may be spaced apart from each of the second upper source/drain region USD2 and the second upper source/drain contact UCA2 in the second horizontal direction DR2. The second through-via TV2 may be spaced apart from the second portion 162 of the second dam structure 160 in the second horizontal direction DR2. For example, a top surface of the second through-via TV2 may be coplanar with each of the top surface of the second interlayer insulating layer 140, the top surface of the second dam structure 160 and the top surface of the second upper source/drain contact UCA2.

For example, each of the first through-via TV1 and the second through-via TV2 may include a conductive material. Although FIG. 6 illustrates that each of the first through-via TV1 and the second through-via TV2 is formed as a single layer, this illustration is intended only for convenience of illustration, and the present disclosure is not limited thereto. For example, each of the first through-via TV1 and the second through-via TV2 may be formed as a multilayer.

The etch stop layer 170 may be disposed on the second interlayer insulating layer 140. The etch stop layer 170 may be formed, for example, conformally. Although each of FIG. 4 to FIG. 6 illustrates that the etch stop layer 170 is formed as a single film, the present disclosure is not limited thereto. In some further embodiments, the etch stop layer 170 may be formed as a stack of multiple films. The etch stop layer 170 may include, as examples, at least one of aluminum oxide, aluminum nitride, hafnium oxide, zirconium oxide, silicon oxide, silicon nitride, silicon oxynitride, or a low-k material. The third interlayer insulating layer 180 may be disposed on the etch stop layer 170. The third interlayer insulating layer 180 may include, for example, at least one of silicon oxide, silicon nitride, silicon oxynitride, or a low-k material.

The first via V1 may extend through the third interlayer insulating layer 180 and the etch stop layer 170 in the vertical direction DR3 so as to be connected to each of the first and second upper source/drain contacts UCA1 and UCA2. The second via V2 may extend through the third interlayer insulating layer 180 and the etch stop layer 170 in the vertical direction DR3 so as to be connected to each of the first and second through-via TV1 and TV2. The third via V3 may extend through the third interlayer insulating layer 180 and the etch stop layer 170 in the vertical direction DR3 so as to be connected to the gate contact CB.

Each of the first to third vias V1, V2, and V3 may include a conductive material. Although each of FIG. 4 to FIG. 6 illustrates that each of the first to third vias V1, V2, and V3 is formed as a single layer, this is intended only for convenience of illustration, and the present disclosure is not limited thereto. That is, in some implementations, each of the first to third vias V1, V2, and V3 may be formed as a multilayer.

The semiconductor device according to some embodiments of the present disclosure may have a structure in which the plurality of upper nanosheets UNW1 as an upper channel region is stacked on the plurality of lower nanosheets BNW1 as a lower channel region, and in which the dam structure 150 is disposed between the through-via TV1 connected to the lower source/drain contact BCA1 and the upper source/drain region USD1, such that a short-circuit between the through-via TV1 and the upper source/drain region USD1 may be suppressed.

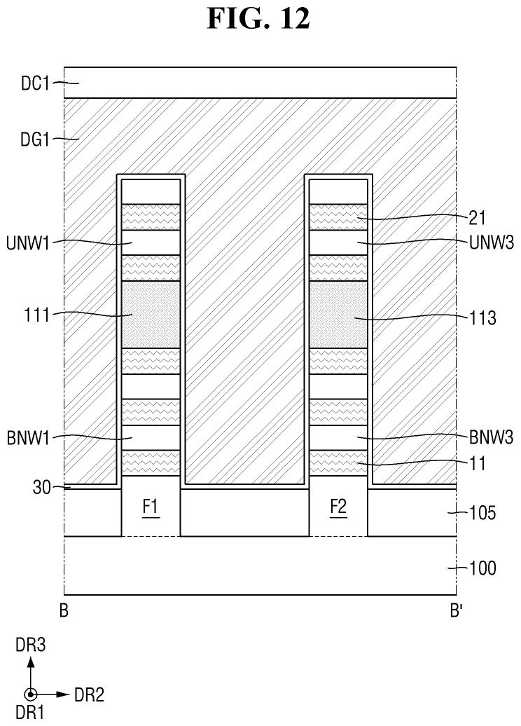

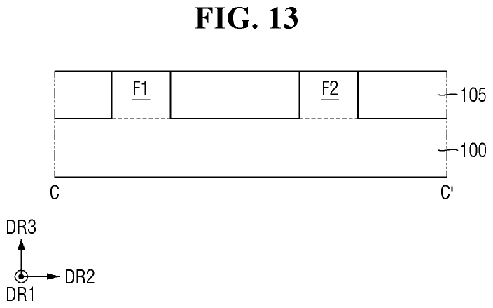

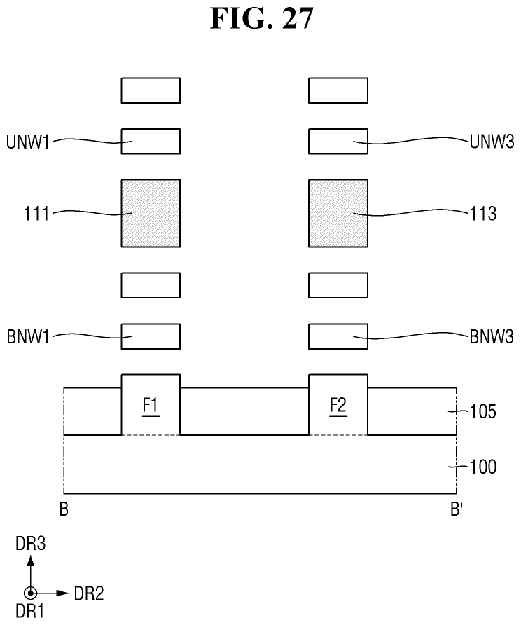

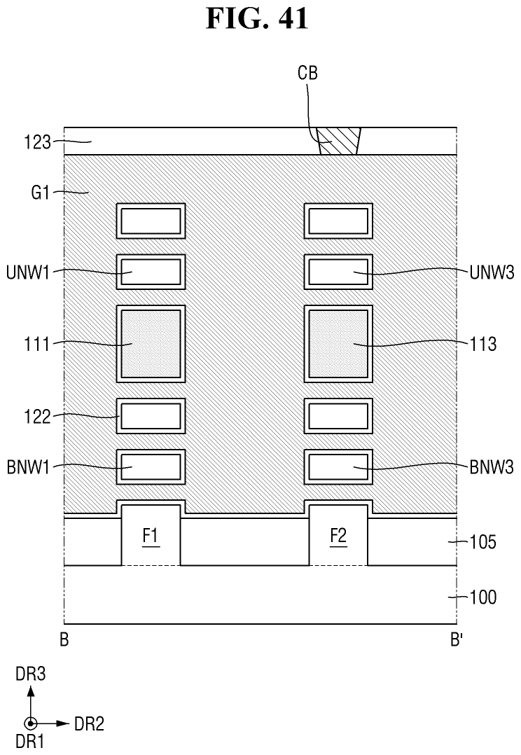

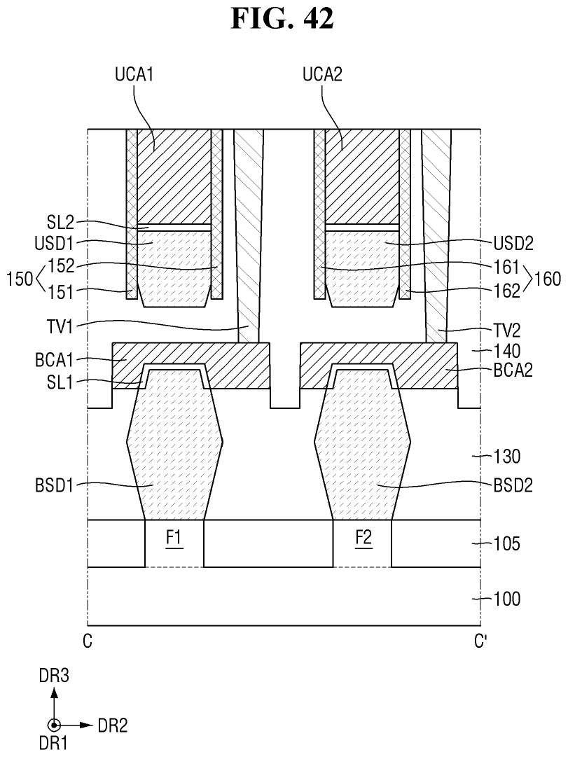

Hereinafter, a method of manufacturing a semiconductor device according to some embodiments of the present disclosure will be described with reference to FIG. 4 to FIG. 42.

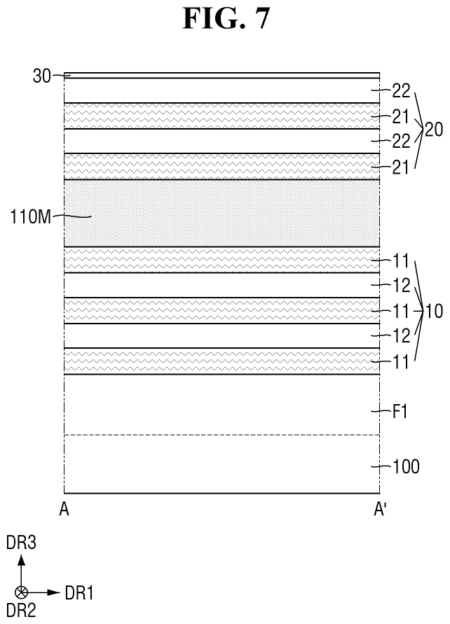

FIG. 7 to FIG. 42 are diagrams of intermediate structures corresponding to intermediate steps for illustrating a method of manufacturing a semiconductor device according to some embodiments of the present disclosure.

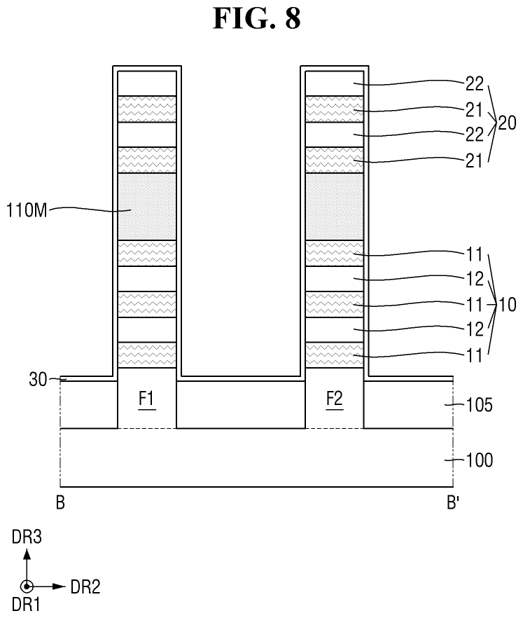

Referring to FIG. 7 and FIG. 8, a first stack structure 10, an isolation material layer 110M and a second stack structure 20 may be sequentially stacked on the substrate 100.

The first stack structure 10 may include first semiconductor layers 11 and second semiconductor layers 12 alternately stacked on top of each other while being disposed on the substrate 100. For example, the first semiconductor layer 11 may constitute each of the bottommost and topmost layers of the first stack structure 10. However, the present disclosure is not limited thereto. In some further embodiments, the first semiconductor layer 11 may constitute the topmost layer of the first stack structure 10. The isolation material layer 110M may include, for example, at least one of silicon nitride (SiN), silicon oxycarbonitride (SiOCN), silicon boron carbonitride (SiBCN), silicon carbonitride (SiCN), silicon oxynitride (SiON) or combinations thereof, as non-limiting examples.

The second stack structure 20 may include third semiconductor layers 21 and fourth semiconductor layers 22 alternately stacked on top of each other while being disposed on the isolation material layer 110M. For example, the third semiconductor layer 21 may constitute the lowermost layer of the second stack structure 20, and the fourth semiconductor layer 22 may constitute the uppermost layer of the second stack structure 20, as non-limiting examples. In some further embodiments, the third semiconductor layer 21 may also constitute the topmost layer of the second stack structure 20. Each of the first semiconductor layer 11 and the third semiconductor layer 21 may include, for example, silicon germanium (SiGe). Each of the second semiconductor layer 12 and the fourth semiconductor layer 22 may include, for example, silicon (Si).

Subsequently, the first active pattern F1 and the second active pattern F2 may be formed on the substrate 100 by etching a portion of each of the first stack structure 10, the isolation material layer 110M, the second stack structure 20, and the substrate 100. Each of the first active pattern F1 and the second active pattern F2 may extend in the first horizontal direction DR1. The second active pattern F2 may be spaced apart from the first active pattern F1 in the second horizontal direction DR2.

Subsequently, the field insulating layer 105 surrounding a sidewall of each of the first active pattern F1 and the second active pattern F2 may be formed on the substrate 100. For example, each of the first active pattern F1 and the second active pattern F2 may protrude upwardly in the vertical direction DR3 beyond the top surface of the field insulating layer 105. Subsequently, a pad oxide layer 30 may be formed to cover each of the field insulating layer 105, the first stack structure 10, the isolation material layer 110M and the second stack structure 20. For example, the pad oxide layer 30 may be conformally formed. The pad oxide layer 30 may include, for example, silicon oxide (SiO₂).

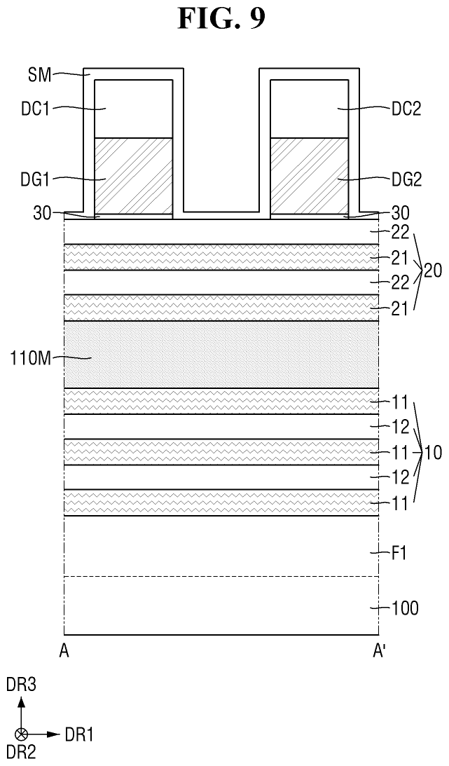

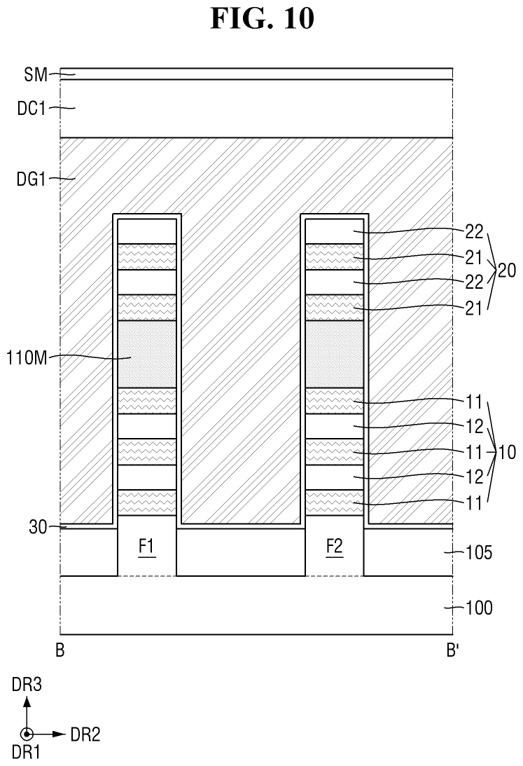

Referring to FIG. 9 and FIG. 10, first and second dummy gates DG1 and DG2 may be formed on the pad oxide layer 30 disposed on the field insulating layer 105, the first stack structure 10, the isolation material layer 110M, and the second stack structure 20. Each of the first and second dummy gates DG1 and DG2 may extend in the second horizontal direction DR2. The second dummy gate DG2 may be spaced apart from the first dummy gate DG1 in the first horizontal direction DR1. Further, a first dummy capping pattern DC1 may be formed on the first dummy gate DG1, and a second dummy capping pattern DC2 may be formed on the second dummy gate DG2. For example, a remaining portion of the pad oxide layer 30 except for a portion thereof overlapping each of the first and second dummy gates DG1 and DG2 in the vertical direction DR3 may be removed.

Subsequently, a spacer material layer SM may be formed to cover a sidewall of each of the first and second dummy gates DG1 and DG2, a sidewall and a top surface of each of the first and second dummy capping patterns DC1 and DC2, a sidewall of the first stack structure 10, a sidewall of the isolation material layer 110M, a sidewall and a top surface of the second stack structure 20, and the top surface of the field insulating layer 105. The spacer material layer SM may be formed conformally. The spacer material layer SM may include, for example, at least one of silicon nitride (SiN), silicon oxycarbonitride (SiOCN), silicon boron carbonitride (SiBCN), silicon carbonitride (SiCN), silicon oxynitride SiON or combinations thereof.

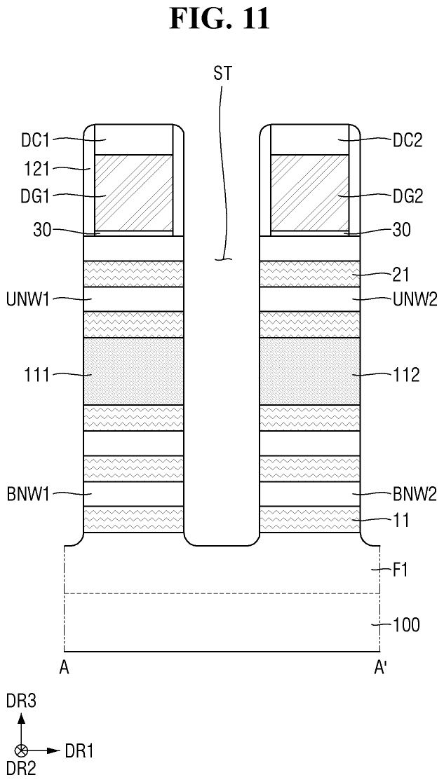

Referring to FIG. 11 to FIG. 13, using the first and second dummy capping patterns DC1 and DC2 and the first and second dummy gates DG1 and DG2 as a mask, the first stack structure 10, the isolation material layer 110M and the second stack structure 20 may be etched to form the source/drain trench ST. For example, the source/drain trench ST may be formed between the first dummy gate DG1 and the second dummy gate DG2 while being disposed on each of the first and second active patterns F1 and F2. For example, the source/drain trench ST may extend into each of the first and second active patterns F1 and F2.

While the source/drain trench ST is being formed, a portion of the spacer material layer (SM of FIG. 9 and FIG. 10) formed on a top surface of each of the first and second dummy capping patterns DC1 and DC2, and a portion of each of the first and second dummy capping patterns DC1 and DC2 may be removed. A portion of the spacer material layer (SM in FIGS. 9 and 10) remaining on the sidewall of each of the first and second dummy gates DG1 and DG2, and a portion of the spacer material layer (SM in FIGS. 9 and 10) remaining on the sidewall of each of remaining first and second dummy capping patterns DC1 and DC2 may act as the gate spacer 121.

For example, after the source/drain trench ST has been formed, portions of the second semiconductor layers (12 in FIG. 9 and FIG. 10) and portions of the fourth semiconductor layers (22 in FIG. 9 and FIG. 10) remaining on the first active pattern F1 and under the first dummy gate DG1 may act as the first plurality of lower nanosheets BNW1 and the first plurality of upper nanosheets UNW1, respectively. Further, after the source/drain trench ST has been formed, portions of the second semiconductor layers (12 in FIG. 9 and FIG. 10) and portions of the fourth semiconductor layers (22 in FIG. 9 and FIG. 10) remaining on the first active pattern F1 and under the second dummy gate DG2 may act as the second plurality of lower nanosheets BNW2 and the second plurality of upper nanosheets UNW2, respectively. Further, after the source/drain trench ST has been formed, portions of the second semiconductor layers (12 in FIG. 9 and FIG. 10) and portions of the fourth semiconductor layers (22 in FIG. 9 and FIG. 10) remaining on the second active pattern F2 and under the first dummy gate DG1 may act as the third plurality of lower nanosheets BNW3 and the third plurality of upper nanosheets UNW3 respectively.

For example, after the source/drain trench ST has been formed, a portion of the isolation material layer (110M in FIG. 9 and FIG. 10) remaining on the first active pattern F1 and under the first dummy gate DG1 may act as the first isolation layer 111. Further, after the source/drain trench ST has been formed, a portion of the isolation material layer (110M in FIG. 9 and FIG. 10) remaining under the second dummy gate DG2 while being disposed on the first active pattern F1 may act as the second isolation layer 112. Further, after the source/drain trench ST has been formed, a portion of the isolation material layer (110M in FIG. 9 and FIG. 10) remaining on the second active pattern F2 and under the first dummy gate DG1 may act as the third isolation layer 113.

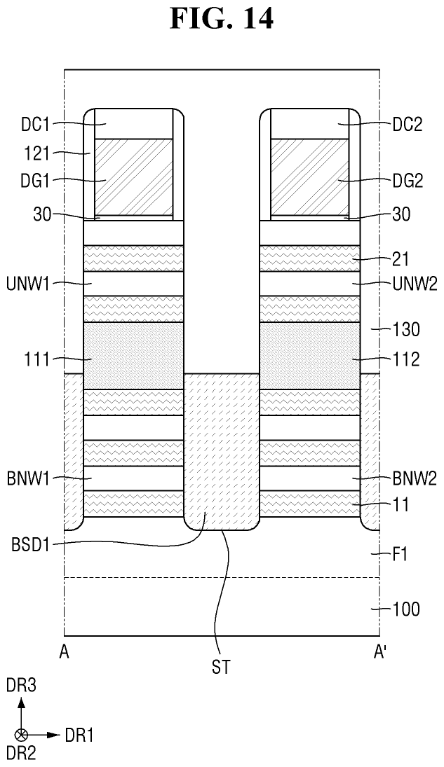

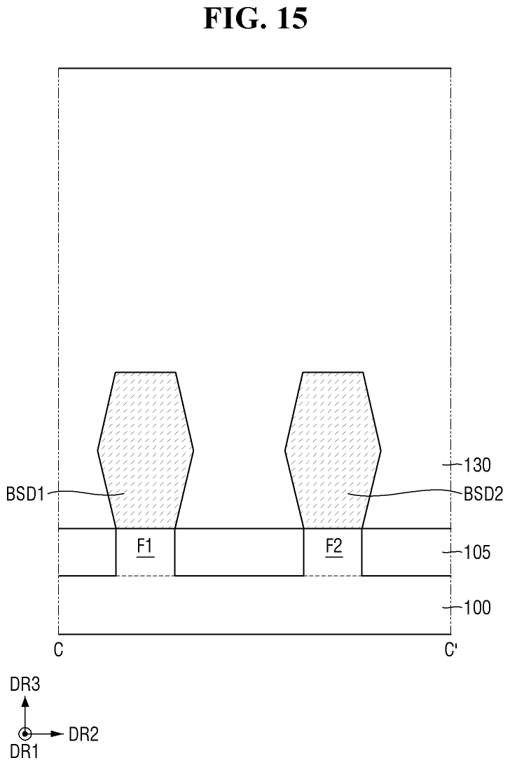

Referring to FIG. 14 and FIG. 15, each of the first lower source/drain region BSD1 and the second lower source/drain region BSD2 may be formed in a lower portion of the source/drain trench ST. For example, the first lower source/drain region BSD1 may be formed on the first active pattern F1, and the second lower source/drain region BSD2 may be formed on the second active pattern F2. For example, a vertical level of a top surface of each of the first and second lower source/drain regions BSD1 and BSD2 may be higher than that of a bottom surface of the first isolation layer 111, as non-limiting examples. Subsequently, the first interlayer insulating layer 130 may be formed on the field insulating layer 105 so as to cover each of the first and second lower source/drain regions BSD1 and BSD2.

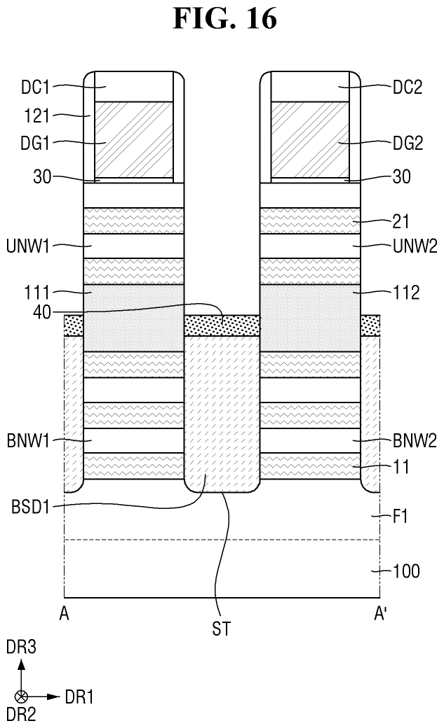

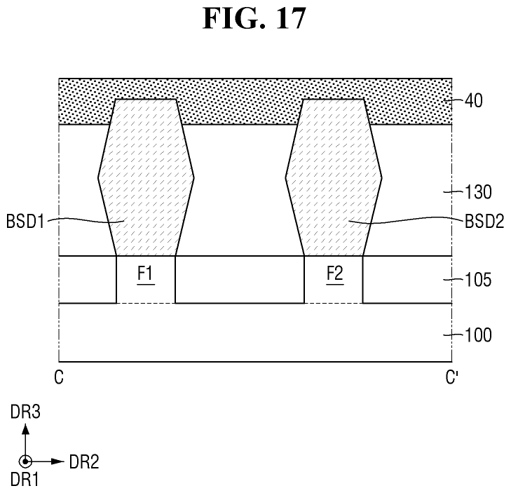

Referring to FIG. 16 and FIG. 17, a portion of the first interlayer insulating layer 130 may be etched. After the portion of the first interlayer insulating layer 130 has been etched, a top portion of each of the first and second lower source/drain regions BSD1 and BSD2 may be exposed. Subsequently, a sacrificial layer 40 may be formed on a top surface of the remaining first interlayer insulating layer 130 and the exposed top portion of each of the first and second lower source/drain regions BSD1 and BSD2. For example, a vertical level of a top surface of the sacrificial layer 40 may be lower than that of a top surface of the first isolation layer 111. For example, the sacrificial layer 40 may include a material having an etch selectivity with respect to each of an oxide film and a nitride film. For example, the sacrificial layer 40 may include polysilicon (PolySi).

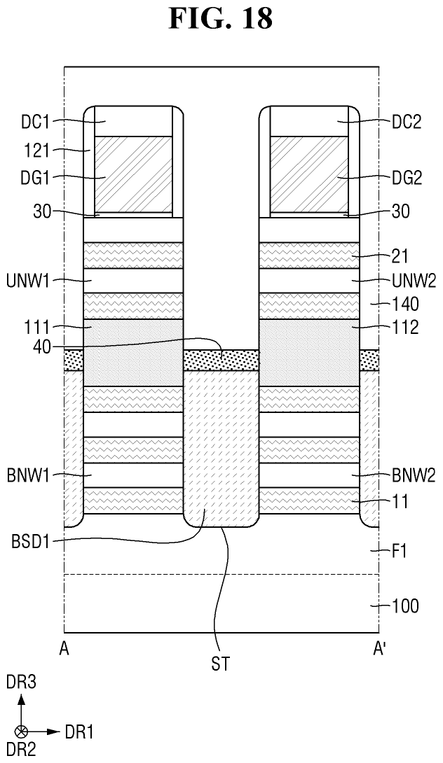

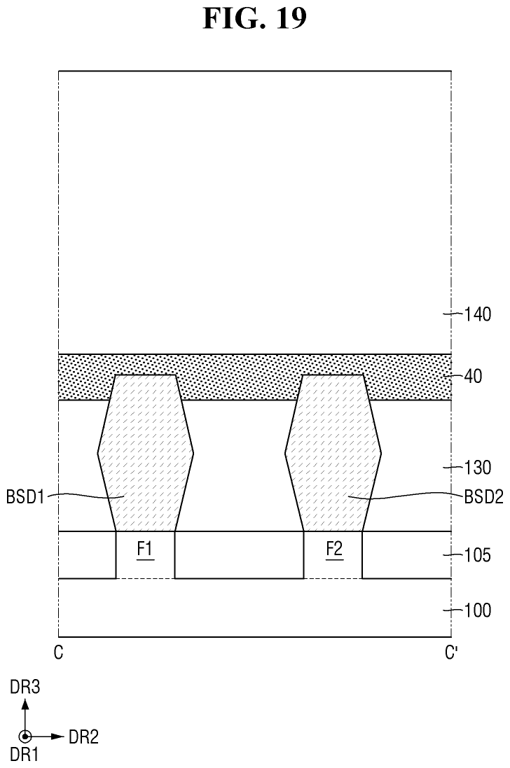

Referring to FIG. 18 and FIG. 19, the second interlayer insulating layer 140 may be formed on the sacrificial layer 40. For example, the second interlayer insulating layer 140 may be formed to cover each of the first and second dummy capping patterns DC1 and DC2.

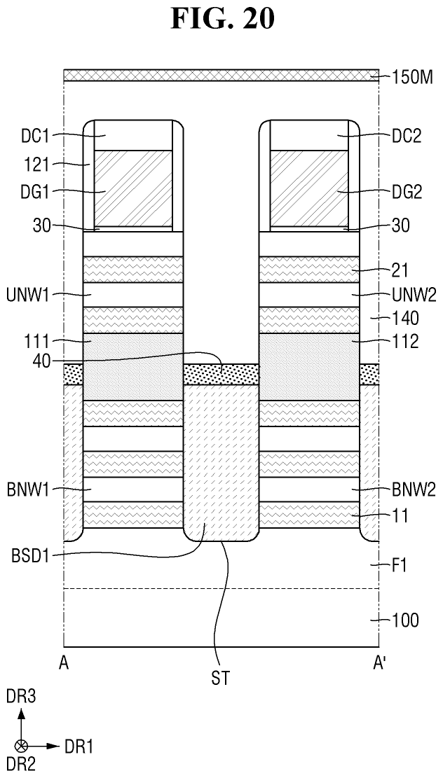

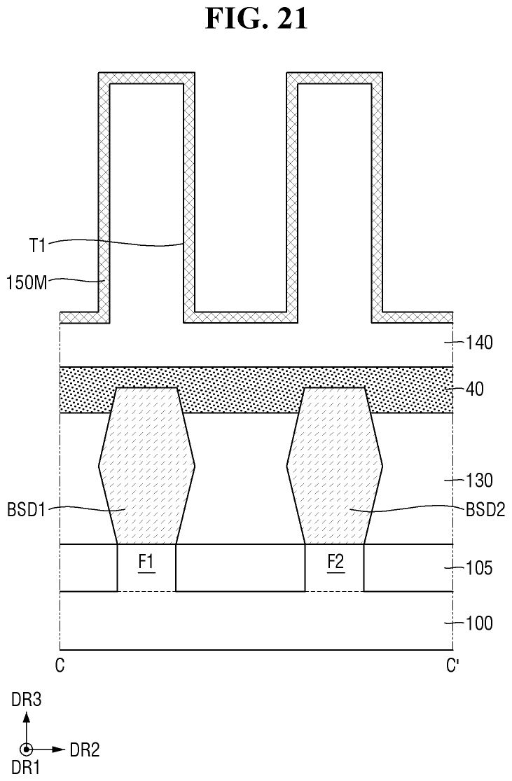

Referring to FIG. 20 and FIG. 21, a portion of the second interlayer insulating layer 140 may be etched to form a first trench T1 defined on the field insulating layer 105. For example, the first trench T1 may be formed on the field insulating layer 105 while being positioned between the first lower source/drain region BSD1 and the second lower source/drain region BSD2. For example, a vertical level of a bottom surface of the first trench T1 may be higher than that of the top surface of the sacrificial layer 40.

Subsequently, a dam material layer 150M may be formed on the second interlayer insulating layer 140. For example, the dam material layer 150M may be conformally formed. The dam material layer 150M may be formed along a sidewall and a bottom surface of the first trench T1.

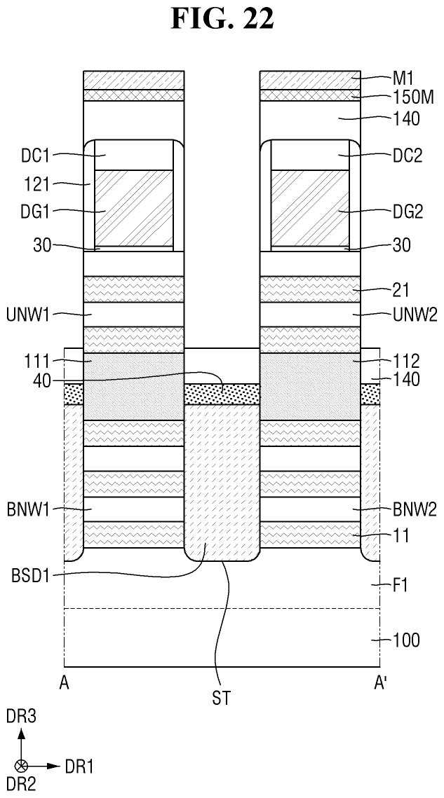

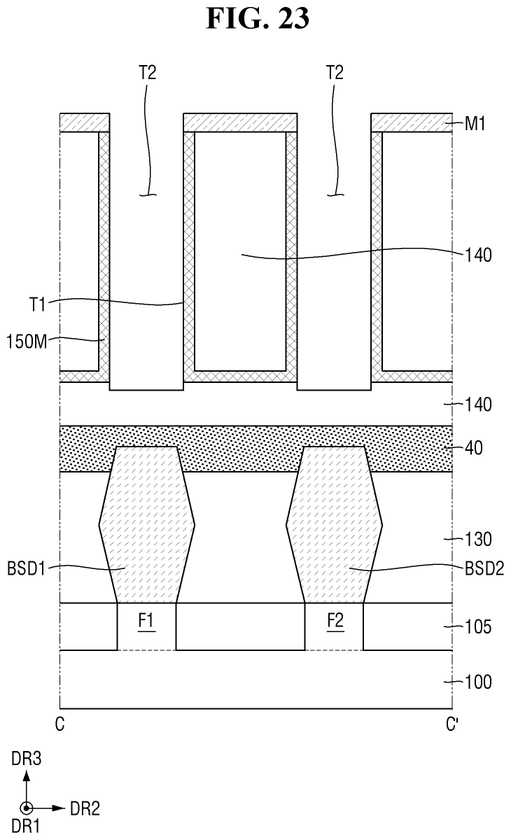

Referring to FIG. 22 and FIG. 23, the second interlayer insulating layer 140 may be additionally formed inside the first trench T1. For example, the second interlayer insulating layer 140 may fill an entirety of an inside of the first trench T1. Subsequently, a first mask pattern M1 may be formed so as to expose a portion of the dam material layer 150M formed on each of the first lower source/drain region BSD1 and the second lower source/drain region BSD2. For example, the first mask pattern M1 may be also formed on a top surface of the dam material layer 150M formed along a sidewall of the first trench T1.

Subsequently, a portion of each of the dam material layer 150M and the second interlayer insulating layer 140 formed on each of the first lower source/drain region BSD1 and the second lower source/drain region BSD2 may be etched using the first mask pattern M1 as a mask. A second trench T2 may be formed in this etching process. For example, a vertical level of the bottom surface of the second trench T2 may be lower than that of the bottom surface of the first trench T1. For example, each of both opposing sidewalls in the first horizontal direction DR1 of each of the first plurality of upper nanosheets UNW1, the second plurality of upper nanosheets UNW2, the third semiconductor layer 21, and the gate spacer 121 may be exposed through the second trench T2. In this case, the dam material layer 150M may remain along and on each of both opposing sidewalls in the second horizontal direction DR2 of the second trench T2.

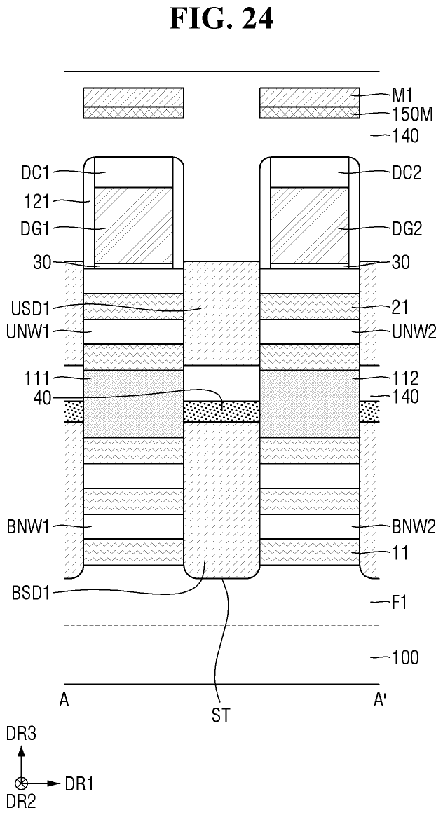

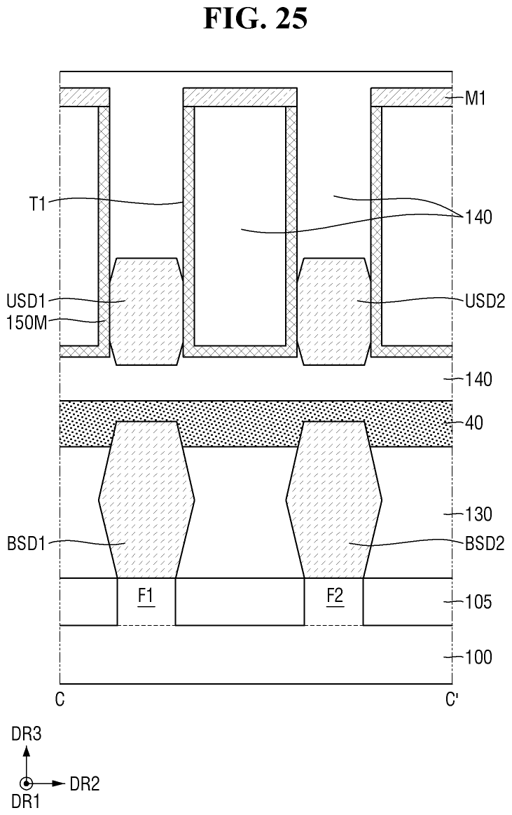

Referring to FIG. 24 and FIG. 25, each of the first upper source/drain region USD1 and the second upper source/drain region USD2 may be formed inside the second trench (T2 in FIG. 23). For example, the first upper source/drain region USD1 may be formed on the first lower source/drain region BSD1. Further, the second upper source/drain region USD2 may be formed on the second lower source/drain region BSD2. Each of the first upper source/drain region USD1 and the second upper source/drain region USD2 may be in contact with the dam material layer 150M. Subsequently, the second interlayer insulating layer 140 may be additionally formed inside the second trench (T2 in FIG. 23). The second interlayer insulating layer 140 may fill an entirety of the inside of the second trench (T2 in FIG. 23).

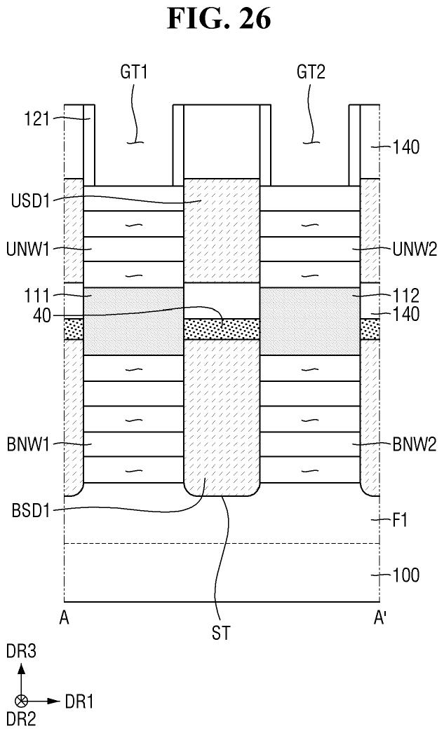

Referring to FIG. 26 to FIG. 28, a top surface of each of the first and second dummy gates (DG1 and DG2 in FIG. 24) may be exposed using a planarization process. Next, each of the first and second dummy gates (DG1 and DG2 in FIG. 24), the first semiconductor layer (11 in FIG. 24), the third semiconductor layer (21 in FIG. 24) and the pad oxide layer (30 in FIG. 24) may be removed. The first dummy gate (DG1 in FIG. 24) may be removed to form a first gate trench GT1. The second dummy gate (DG2 in FIG. 24) may be removed to form a second gate trench GT2.

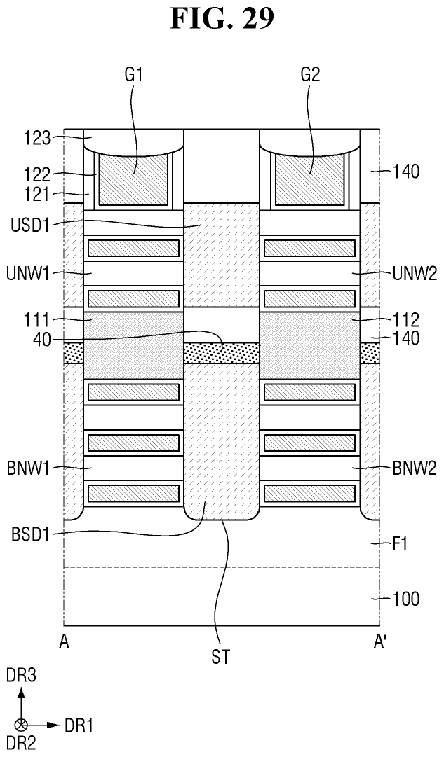

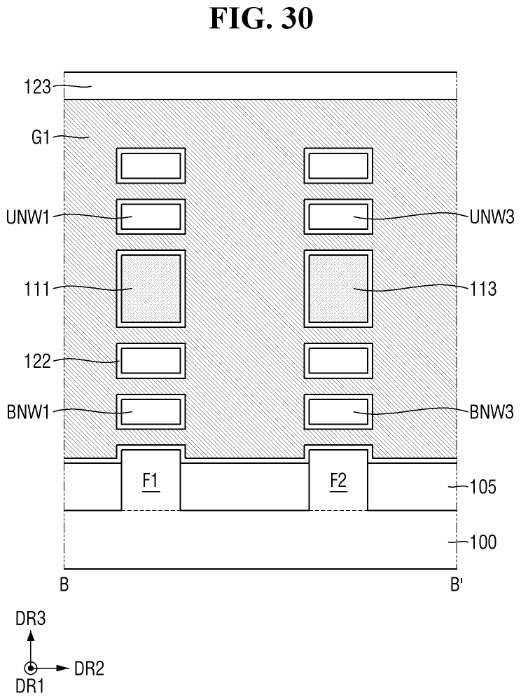

Referring to FIG. 29 and FIG. 30, under the first gate trench GT1, the gate insulating layer 122 and the first gate electrode G1 may be formed in each of spaces obtained via the removal of the first semiconductor layers (11 in FIG. 24) and the third semiconductor layers (21 in FIG. 24). Further, the gate insulating layer 122, the first gate electrode G1 and the capping pattern 123 may be sequentially formed in the first gate trench GT1. Further, under the second gate trench GT2, the gate insulating layer 122 and the second gate electrode G2 may be formed in each of the spaces obtained via the removal of the first semiconductor layers (11 in FIG. 24) and the third semiconductor layers (21 in FIG. 24). Further, the gate insulating layer 122, the second gate electrode G2 and the capping pattern 123 may be sequentially formed in the second gate trench GT2.

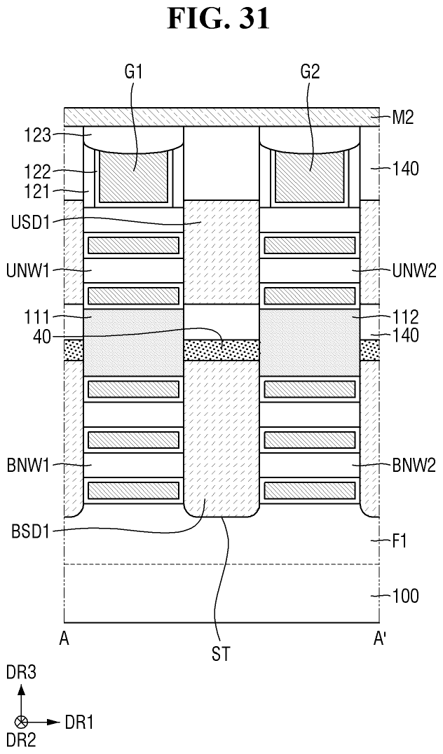

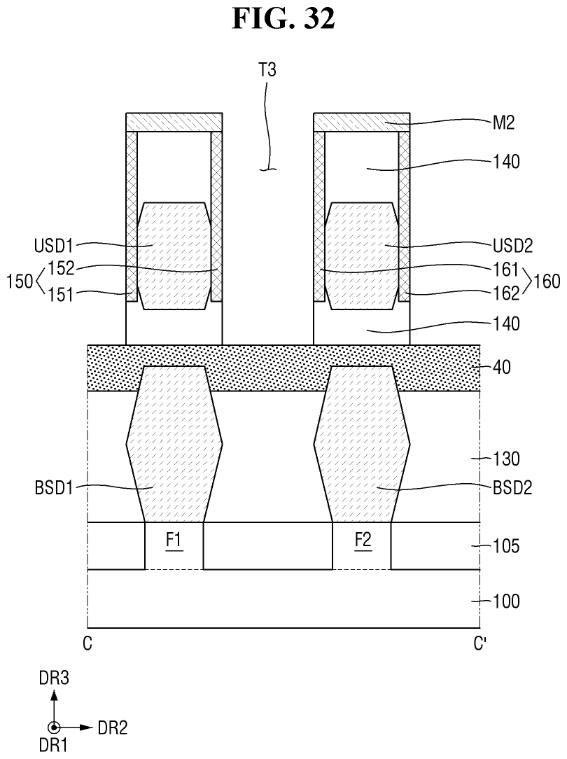

Referring to FIG. 31 and FIG. 32, a second mask pattern M2 may be formed on the second interlayer insulating layer 140 and the capping pattern 123. The second mask pattern M2 may be formed to expose a portion of the second interlayer insulating layer 140 formed on each of both opposing sides in the second horizontal direction DR2 of each of the first upper source/drain region USD1 and the second upper source/drain region USD2 while being disposed on the field insulating layer 105.

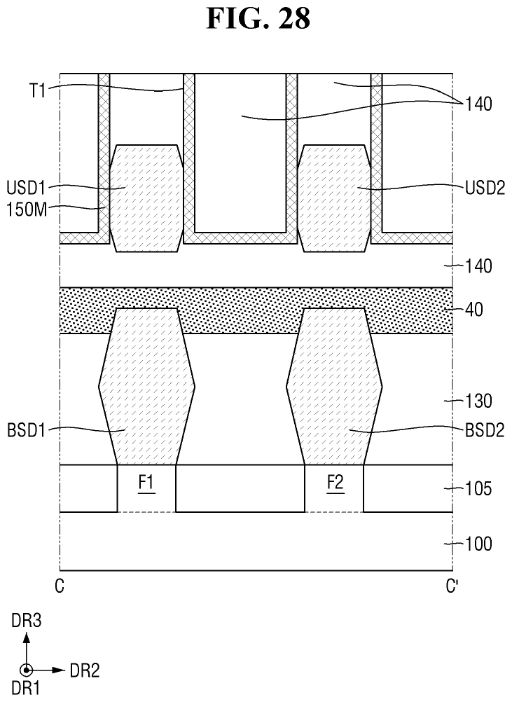

Then, using the second mask pattern M2 as a mask, the exposed portion of the second interlayer insulating layer 140 and a portion of the dam material layer (150M in FIG. 28) formed along a bottom surface of the first trench (T1 in FIG. 28) may be etched, so that a third trench T3 is may be formed. The third trench T3 may expose a portion of the sacrificial layer 40. Further, the dam material layer (150M in FIG. 28) may remain along a sidewall of the third trench T3. After the third trench T3 has been formed, the remaining portions of the dam material layer (150M in FIG. 28) may be defined as the first dam structure 150 and the second dam structure 160. The first dam structure 150 may include the first portion 151 and the second portion 152 respectively in contact with both opposing sidewalls in the second horizontal direction DR2 of the first upper source/drain region USD1. The second dam structure 160 may include the first portion 161 and the second portion 162 respectively in contact with both opposing sidewalls in the second horizontal direction DR2 of the second upper source/drain region USD2.

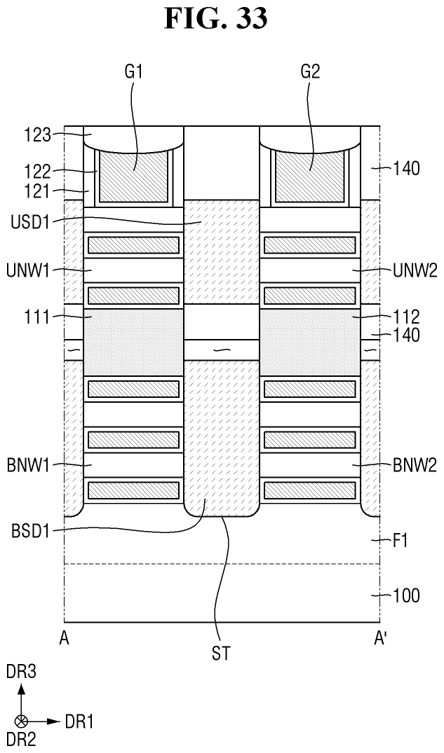

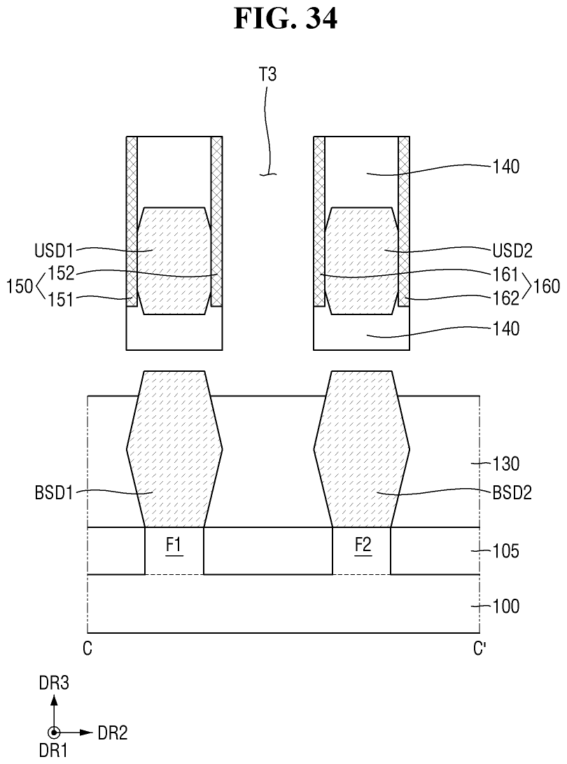

Referring to FIG. 33 and FIG. 34, the sacrificial layer (40 in FIG. 32 and FIG. 33) exposed through the third trench T3 may be removed. Thus, a top of each of the first lower source/drain region BSD1 and the second lower source/drain region BSD2 may be exposed.

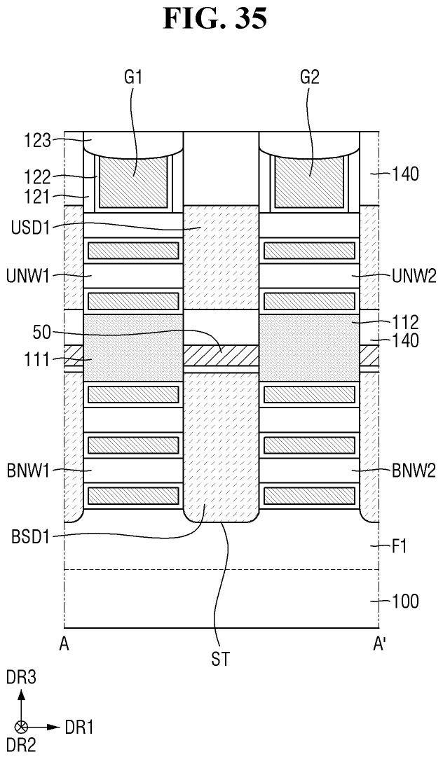

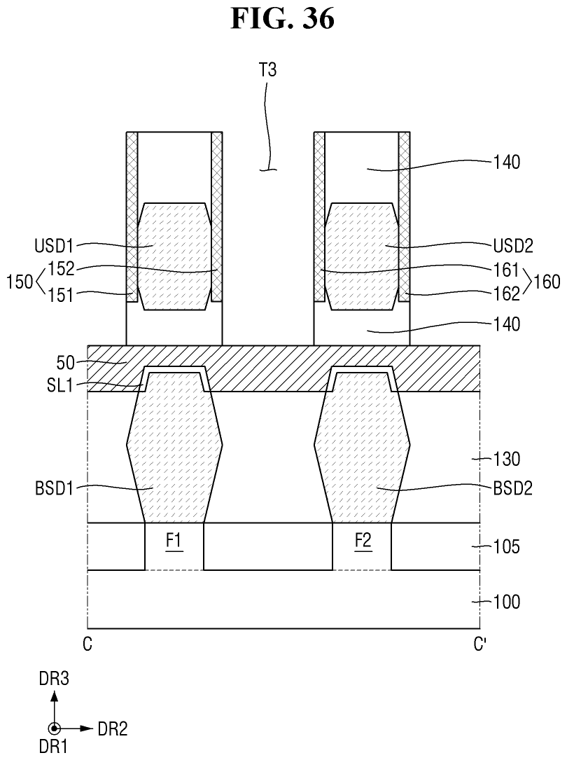

Referring to FIG. 35 and FIG. 36, a conductive material layer 50 may be formed in a space obtained via the removal of the sacrificial layer (40 in FIG. 32 and FIG. 33). For example, the conductive material layer 50 may include a conductive material. Further, the first silicide layer SL1 may be formed along and at a boundary surface of the first lower source/drain region BSD1 and the conductive material layer 50. The first silicide layer SL1 may be formed along and at a boundary surface of the second lower source/drain region BSD2 and the conductive material layer 50.

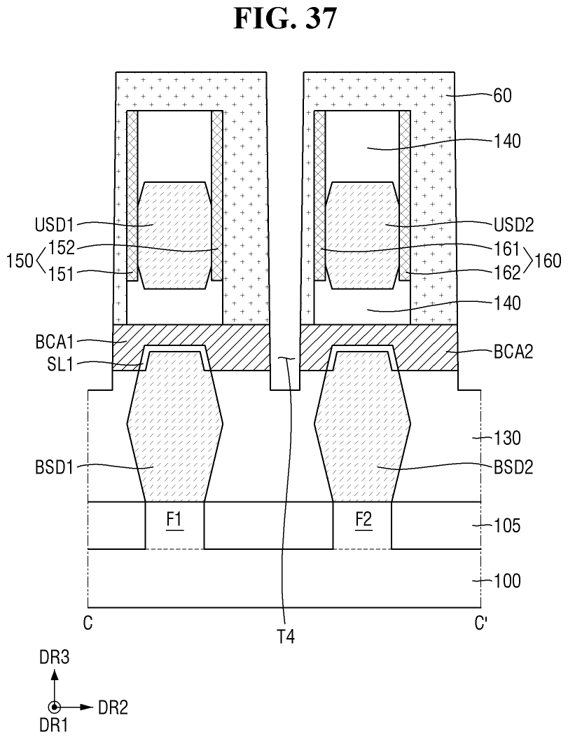

Referring to FIG. 37, a protective layer 60 may be formed on the conductive material layer (50 of FIG. 36) so as to cover each of the second interlayer insulating layer 140, the first dam structure 150 and the second dam structure 160. The protective layer 60 may include, for example, SOH.

Subsequently, a fourth trench T4 may be formed on the field insulating layer 105 so as to extend through the protective layer 60 and the conductive material layer (50 in FIG. 36) in the vertical direction DR3 and extend into the first interlayer insulating layer 130. The conductive material layer (50 in FIG. 36) may be divided into two portions spaced from each other via the fourth trench T4. After the fourth trench T4 has been formed, a portion of the conductive material layer (50 in FIG. 36) remaining on the first lower source/drain region BSD1 may be defined as the first lower source/drain contact BCA1. Further, after the fourth trench T4 has been formed, a portion of the conductive material layer (50 in FIG. 36) remaining on the second lower source/drain region BSD2 may be defined as the second lower source/drain contact BCA2.

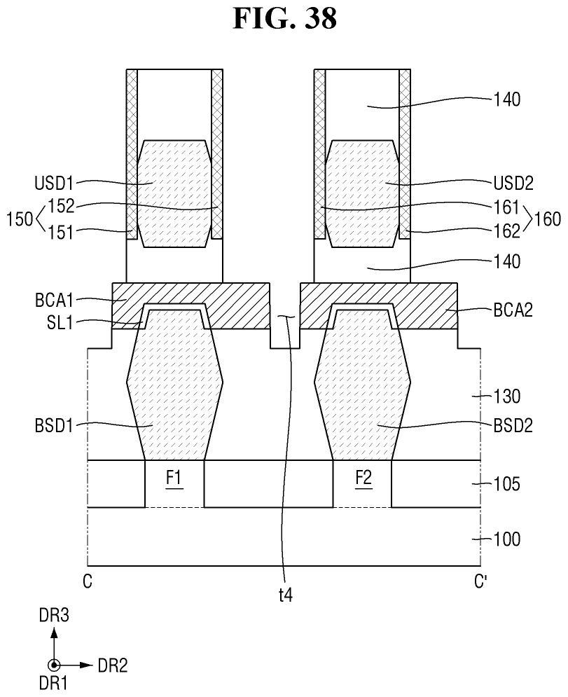

Referring to FIG. 38, the protective layer 60 may be removed.

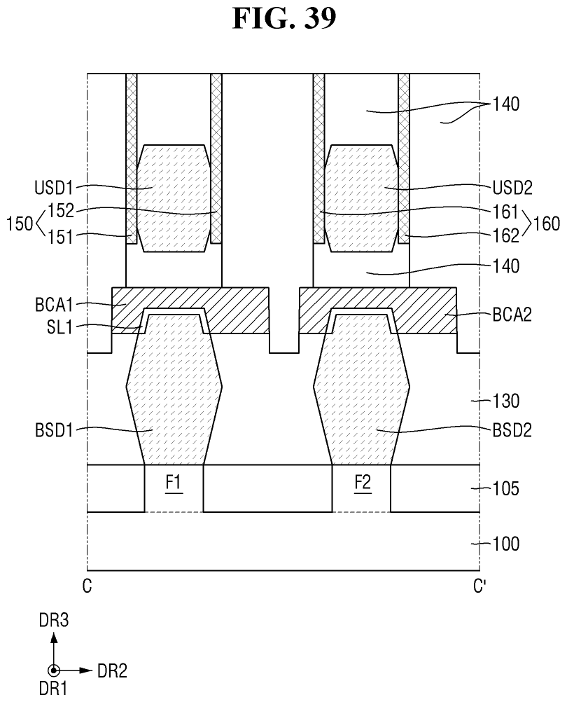

Referring to FIG. 39, the second interlayer insulating layer 140 may be additionally formed so as to cover the first interlayer insulating layer 130, the first lower source/drain contact BCA1, the second lower source/drain contact BCA2, the first dam structure 150 and the second dam structure 160.

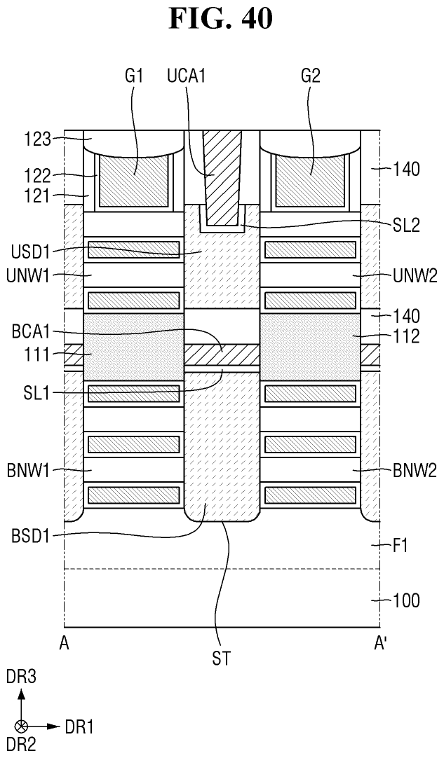

Referring to FIG. 40 to FIG. 42, the first upper source/drain contact UCA1 may be formed on the first upper source/drain region USD1 and between the first portion 151 of the first dam structure 150 and the second portion 152 of the first dam structure 150. the second upper source/drain contact UCA2 may be formed on the second upper source/drain region USD2 and between the first portion 161 of the second dam structure 160 and the second portion 162 of the second dam structure 160. Further, the second silicide layer SL2 may be formed along and at a boundary surface of the first upper source/drain region USD1 and the first upper source/drain contact UCA1. The second silicide layer SL2 may be formed along and at a boundary surface of the second upper source/drain region USD2 and the second upper source/drain contact UCA2.

Further, the gate contact CB may be formed so as to extend through the capping pattern 123 in the vertical direction DR3 and thus be connected to the first gate electrode G1. Further, the first through-via TV1 extending through the second interlayer insulating layer 140 in the vertical direction DR3 so as to be connected to the first lower source/drain contact BCA1 may be formed on a sidewall of the second portion 152 of the first dam structure 150 facing in the second horizontal direction DR2. Further, the second through-via TV2 extending through the second interlayer insulating layer 140 in the vertical direction DR3 so as to be connected to the second lower source/drain contact BCA2 may be formed on a sidewall of the second portion 162 of the second dam structure 160 facing in the second horizontal direction DR2.

Referring to FIG. 4 to FIG. 6, the etch stop layer 170 and the third interlayer insulating layer 180 may be sequentially formed on the second interlayer insulating layer 140. Subsequently, each first via V1 may be formed so as to extend through the third interlayer insulating layer 180 and the etch stop layer 170 in the vertical direction DR3 and thus to be connected to each of the first and second upper source/drain contacts UCA1 and UCA2. Further, each second via V2 may be formed so as to extend through the third interlayer insulating layer 180 and the etch stop layer 170 in the vertical direction DR3 and then to be connected to each of the first and second through-vias TV1 and TV2. Further, the third via V3 may be formed so as to extend through the third interlayer insulating layer 180 and the etch stop layer 170 in the vertical direction DR3 and then to be connected to the gate contact CB. In this manufacturing process, the semiconductor device as shown in FIG. 4 to FIG. 6 may be manufactured.

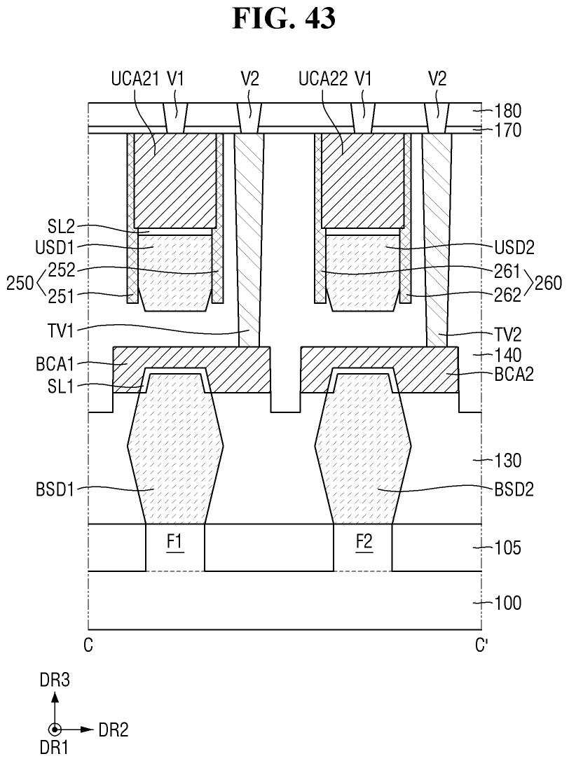

Hereinafter, a semiconductor device according to some further embodiments of the present disclosure will be described with reference to FIG. 43. Following description will be based on differences thereof from the semiconductor device as shown in FIG. 1 to FIG. 6.

FIG. 43 is a cross-sectional view for illustrating a semiconductor device according to some additional embodiments of the present disclosure.

Referring to FIG. 43, in the semiconductor device according to some additional embodiments of the present disclosure, a width in the second horizontal direction DR2 of the first upper source/drain contact UCA21 may be larger than a width in the second horizontal direction DR2 of the first upper source/drain region USD1. Further, a width in the second horizontal direction DR2 of the second upper source/drain contact UCA22 may be greater than a width in the second horizontal direction DR2 of the second upper source/drain region USD2.

A thickness in the second horizontal direction DR2 of a portion of the first portion 251 of the first dam structure 250 in contact with the first upper source/drain region USD1 may be greater than a thickness in the second horizontal direction DR2 of a portion of the first portion 251 of the first dam structure 250 in contact with the first upper source/drain contact UCA21. A thickness in the second horizontal direction DR2 of a portion of the second portion 252 of the first dam structure 250 in contact with the first upper source/drain region USD1 may be greater than a thickness in the second horizontal direction DR2 of a portion of the second portion 252 of the first dam structure 250 in contact with the first upper source/drain contact UCA21.

Further, a thickness in the second horizontal direction DR2 of a portion of the first portion 261 of the second dam structure 260 in contact with the second upper source/drain region USD1 may be greater than a thickness in the second horizontal direction DR2 of a portion of the first portion 261 of the second dam structure 260 in contact with the second upper source/drain contact UCA22. A thickness in the second horizontal direction DR2 of a portion of the second portion 262 of the second dam structure 260 in contact with the second upper source/drain region USD2 may be greater than a thickness in the second horizontal direction DR2 of a portion of the second portion 262 of the second dam structure 260 in contact with the second upper source/drain contact UCA22.

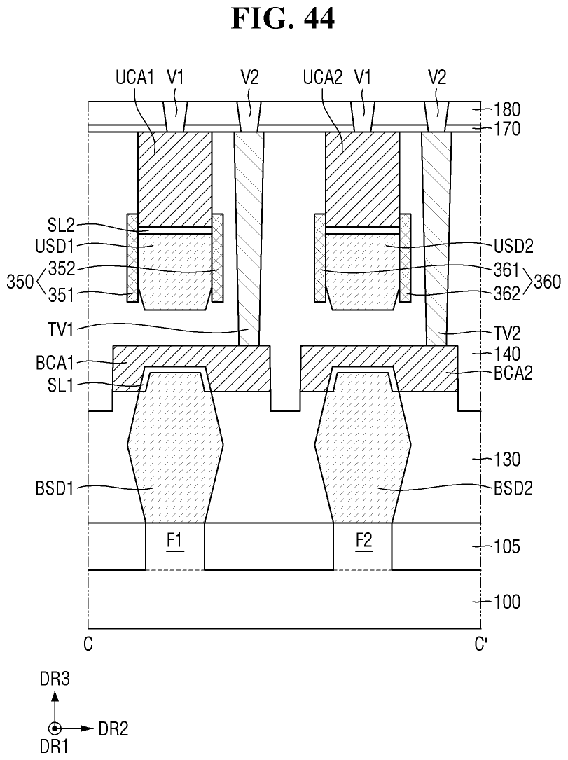

Hereinafter, a semiconductor device according to additional embodiments of the present disclosure will be described with reference to FIG. 44. Following description will be based on differences thereof from the semiconductor device as shown in FIG. 1 to FIG. 6.

FIG. 44 is a cross-sectional view for illustrating a semiconductor device according to additional embodiments of the present disclosure.

Referring to FIG. 44, in the semiconductor device according to additional embodiment of the present disclosure, each of the first dam structure 350 and the second dam structure 360 may be spaced apart from the etch stop layer 170 in the vertical direction DR3.

For example, a vertical level of each of a top surface of the first portion 351 of the first dam structure 350 and a top surface of the second portion 352 of the first dam structure 350 may be lower than a vertical level of each of a top surface of the second interlayer insulating layer 140 and a top surface of the first upper source/drain contact UCA1. Further, a vertical level of each of a top surface of the first portion 361 of the second dam structure 360 and a top surface of the second portion 362 of the second dam structure 360 may be lower than a vertical level of each of a top surface of the second interlayer insulating layer 140 and a top surface of the second upper source/drain contact of UCA2.

For example, each of both opposing sidewalls in the second horizontal direction DR2 of a portion of the first upper source/drain contact UCA1 positioned above a top surface of the first dam structure 350 may contact the second interlayer insulating layer 140. Further, each of both opposing sidewalls in the second horizontal direction DR2 of a portion of the second upper source/drain contact UCA2 positioned above a top surface of the second dam structure 360 may contact the second interlayer insulating layer 140.

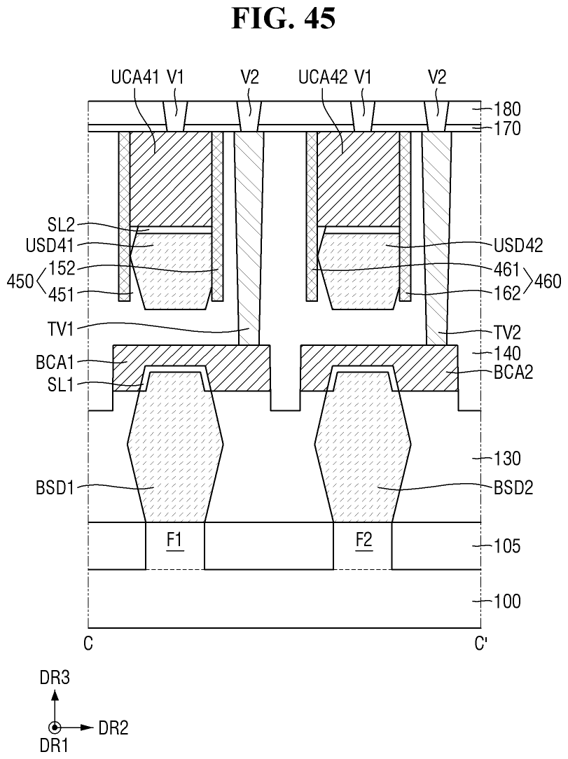

Hereinafter, a semiconductor device according to some additional embodiments of the present disclosure will be described with reference to FIG. 45. Following description will be based on differences thereof from the semiconductor device as shown in FIG. 1 to FIG. 6.

FIG. 45 is a cross-sectional view for illustrating a semiconductor device according to some still yet further embodiments of the present disclosure.

Referring to FIG. 45, in the semiconductor device according to some additional embodiments of the present disclosure, each of the first upper source/drain region USD41 and the second upper source/drain region USD42 may be formed asymmetrically in the second horizontal direction DR2.

For example, a region size of a portion of the first upper source/drain region USD41 in contact with the first portion 451 of the first dam structure 450 may be smaller than a region size of a portion of the first upper source/drain region USD41 in contact with the second portion 152 of the first dam structure 450. Further, a region size of a portion of the second upper source/drain region USD42 in contact with the first portion 461 of the second dam structure 460 may be smaller than a region size of a portion of the second upper source/drain region USD42 in contact with the second portion 162 of the second dam structure 460.

The first upper source/drain contact UCA41 may be disposed on the first upper source/drain region USD41 and between the first portion 451 of the first dam structure 450 and the second portion 152 of the first dam structure 450. The second upper source/drain contact UCA42 may be disposed on the second upper source/drain region USD42 and between the first portion 461 of the second dam structure 460 and the second portion 162 of the second dam structure 460.

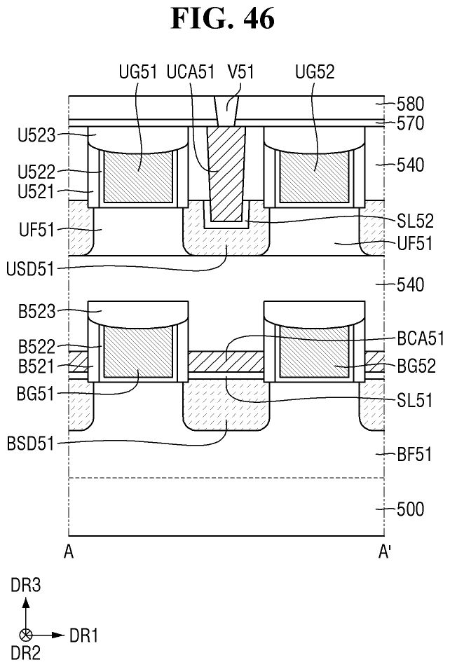

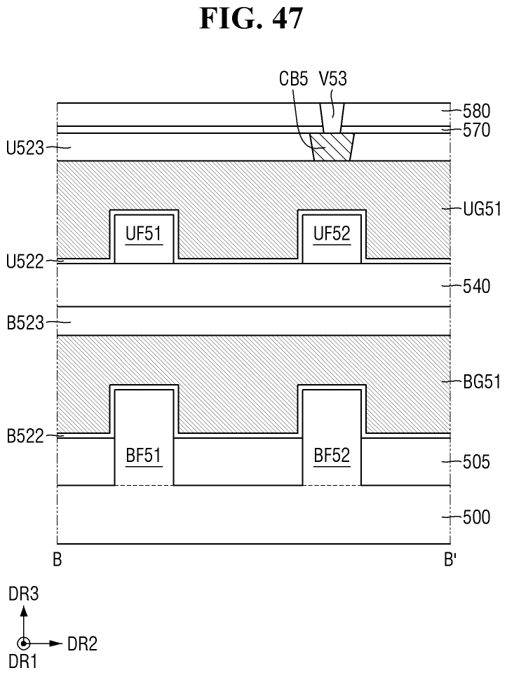

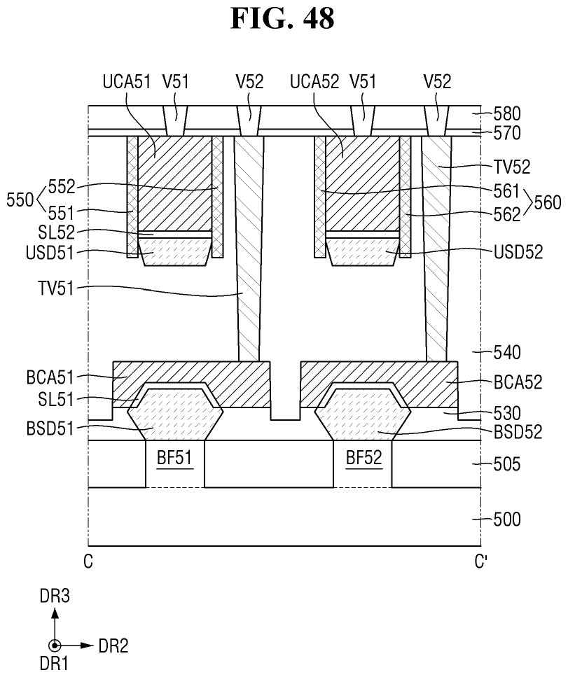

Hereinafter, a semiconductor device according to some additional embodiments of the present disclosure will be described with reference to FIG. 46 to FIG. 48. The following description will be based on differences thereof from the semiconductor device as shown in FIG. 1 to FIG. 6.

FIG. 46 to FIG. 48 are cross-sectional views for illustrating a semiconductor device according to additional embodiments of the present disclosure.

Referring to FIG. 46 to FIG. 48, the semiconductor device according to additional embodiments of the present disclosure may include a fin-type transistor (FinFET). For example, the semiconductor device according to additional embodiments of the present disclosure may include a substrate 500, first and second lower active patterns BF51 and BF52, first and second upper active patterns UF51 and UF52, a field insulating layer 505, first and second lower gate electrodes BG51 and BG52, first and second upper gate electrodes UG51 and UG52, a lower gate spacer B521, an upper gate spacer U521, a lower gate insulating layer B522, an upper gate insulating layer U522, a lower capping pattern B523, an upper capping pattern U523, first and second lower source/drain regions BSD51 and BSD52, first and second upper source/drain regions USD51 and USD52, first and second lower source/drain contacts BCA51 and BCA52, first and second upper source/drain contacts UCA51 and UCA52, first and second silicide layers SL51 and SL52, a gate contact CB, a first interlayer insulating layer 530, a second interlayer insulating layer 540, first and second dam structures 550 and 560, first and second through-vias TV51 and TV52, an etch stop layer 570, a third interlayer insulating layer 580, and first to third vias V51, V52, and V53. Each of the above components having the same or similar names as or to those the components as described in FIG. 1 to FIG. 6, may include the same material as that of each of the components as described in FIG. 1 to FIG. 6.

Each of the first and second lower active patterns BF51 and BF52 may extend in the first horizontal direction DR1 while being disposed on the substrate 500. The second lower active pattern BF52 may be spaced apart from the first lower active pattern BF51 in the second horizontal direction DR2. The field insulating layer 505 may surround a sidewall of each of the first and second lower active patterns BF51 and BF52 while being disposed on the substrate 500. Each of the first and second lower gate electrodes BG51 and BG52 may extend in the second horizontal direction DR2 while being disposed on the field insulating layer 505 and the first and second lower active patterns BF51 and BF52. The second lower gate electrode BG52 may be spaced apart from the first lower gate electrode BG51 in the first horizontal direction DR1.

The lower gate spacer B521 may extend in the second horizontal direction DR2 while being disposed on each of both opposing sidewalls of each of the first and second lower gate electrodes BG51 and BG52. The lower gate insulating layer B522 may be disposed between each of the first and second lower gate electrodes BG51 and BG52 and each of the first and second lower active patterns BF51 and BF52. Further, the lower gate insulating layer B522 may be disposed between each of the first and second lower gate electrodes BG51 and BG52 and the lower gate spacer B521. The lower capping pattern B523 may extend in the second horizontal direction DR2 while being disposed on each of the first and second lower gate electrodes BG51 and BG52.

The first lower source/drain region BSD51 may be disposed on each of both opposing sides of each of the first and second lower gate electrodes BG51 and BG52 while being disposed on the first lower active pattern BF51. The second lower source/drain region BSD52 may be disposed on each of both opposing sides of each of the first and second lower gate electrodes BG51 and BG52 while being disposed on the second lower active pattern BF52. The first interlayer insulating layer 530 may surround at least a portion of each of the first and second lower source/drain regions BSD51 and BSD52 while being disposed on the field insulating layer 505.

The first lower source/drain contact BCA51 may be connected to the first lower source/drain region BSD51. The second lower source/drain contact BCA52 may be connected to the second lower source/drain region BSD52. The second lower source/drain region BSD52 may be spaced apart from the first lower source/drain region BSD51 in the second horizontal direction DR2. The first silicide layer SL51 may be disposed between each of the first and second lower source/drain regions BSD51 and BSD52 and each of the first and second lower source/drain contacts BCA51 and BCA52. The second interlayer insulating layer 540 may cover each of the lower gate spacer B521, the lower capping pattern B523, and the first and second lower source/drain contacts BCA51 and BCA52 while being disposed on the first interlayer insulating layer 530.

Each of the first and second upper active patterns UF51 and UF52 may be disposed inside the second interlayer insulating layer 540. The first upper active pattern UF51 may overlap the first lower active pattern BF51 in the vertical direction DR3. The first upper active pattern UF51 may overlap the first lower active pattern BF51 in the vertical direction DR3. The second upper active pattern UF52 may overlap the second lower active pattern BF52 in the vertical direction DR3. For example, the first upper active pattern UF51 may be divided to portions spaced from each other in the first horizontal direction DR1. The second upper active pattern UF52 may be divided to portions spaced from each other in the first horizontal direction DR1. However, the present disclosure is not limited thereto. In some further embodiments, the first upper active pattern UF51 may be integrally formed, and the second upper active pattern UF52 may be integrally formed. The second interlayer insulating layer 540 may be disposed between each of the first and second upper active patterns UF51 and UF52 and the lower capping pattern B523.

Each of the first and second upper gate electrodes UG51 and UG52 may be disposed inside the second interlayer insulating layer 540. Each of the first and second upper gate electrodes UG51 and UG52 may extend in the second horizontal direction DR2 while being disposed on each of the first and second upper active patterns UF51 and UF51. The second upper gate electrode UG52 may be spaced apart from the first upper gate electrode UG51 in the first horizontal direction DR1. For example, the first upper gate electrode UG51 may overlap the first lower gate electrode BG51 in the vertical direction DR3. The second upper gate electrode UG52 may overlap the second lower gate electrode BG52 in the vertical direction DR3.

The upper gate spacer U521 may extend in the second horizontal direction DR2 while being disposed on each of both opposing sidewalls of each of the first and second upper gate electrodes UG51 and UG52. The upper gate insulating layer U522 may be disposed between each of the first and second upper gate electrodes UG51 and UG52 and each of the first and second upper active patterns UF51 and UF52. Further, the upper gate insulating layer U522 may be disposed between each of the first and second upper gate electrodes UG51 and UG52 and the upper gate spacer U521. The upper capping pattern U523 may extend in the second horizontal direction DR2 while being disposed on each of the first and second upper gate electrodes UG51 and UG52.

The first upper source/drain region USD51 may be disposed on each of both opposing sides of each of the first and second upper gate electrodes UG51 and UG52. The first upper source/drain region USD51 may divide the first upper active pattern UF51 into two portions spaced from each other. The second upper source/drain region USD52 may be disposed on each of both opposing sides of each of the first and second upper gate electrodes UG51 and UG52. The second upper source/drain region USD52 may divide the second upper active pattern UF52 into two portions spaced from each other. Each of the first and second upper source/drain regions USD51 and USD52 may overlap each of the first and second lower source/drain regions BSD51 and BSD52 in the vertical direction DR3.

The first upper source/drain contact UCA51 may be connected to the first upper source/drain region USD51. The second upper source/drain contact UCA52 may be connected to the second upper source/drain region USD52. The second upper source/drain contact UCA52 may be spaced apart from the first upper source/drain contact UCA51 in the second horizontal direction DR2. For example, a top surface of each of the first and second upper source/drain contacts UCA51 and UCA52 may be coplanar with a top surface of the second interlayer insulating layer 540. The second silicide layer SL52 may be disposed between each of the first and second upper source/drain regions USD51 and USD52 and each of the first and second upper source/drain contacts UCA51 and UCA52. For example, the gate contact CBS may extend through the upper capping pattern U523 in the vertical direction DR3 so as to be connected to the first upper gate electrode UG51.

The first dam structure 550 may be disposed on each of both opposing sidewalls in the second horizontal direction DR2 of each of the first upper source/drain region USD51 and the first upper source/drain contact UCA51. A first portion 551 of the first dam structure 550 may contact a first sidewall of each of the first upper source/drain region USD51 and the first upper source/drain contact UCA51. A second portion 552 of the first dam structure 550 may contact a second sidewall of each of the first upper source/drain region USD51 and the first upper source/drain contact UCA51. The second dam structure 560 may be disposed on each of both opposing sidewalls in the second horizontal direction DR2 of each of the second upper source/drain region USD52 and the second upper source/drain contact UCA52. A first portion 561 of the second dam structure 560 may contact a first sidewall of each of the second upper source/drain region USD52 and the second upper source/drain contact UCA52. A second portion 562 of the second dam structure 560 may contact a second sidewall of each of the second upper source/drain region USD52 and the second upper source/drain contact UCA52. A top surface of each of the first and second dam structures 550 and 560 may be coplanar with a top surface of the second interlayer insulating layer 540.

The first through-via TV51 may be spaced apart from the second portion 552 of the first dam structure 550 in the second horizontal direction DR2. The first through-via TV51 may extend through the second interlayer insulating layer 540 in the vertical direction DR3 so as to be connected to the first lower source/drain contact BCA51. The second through-via TV52 may be spaced apart from the second portion 562 of the second dam structure 560 in the second horizontal direction DR2. The second through-via TV52 may extend through the second interlayer insulating layer 540 in the vertical direction DR3 so as to be connected to the second lower source/drain contact BCA52. A top surface of each of the first and second through-via TV51 and TV52 may be coplanar with a top surface of each of the first and second dam structures 550 and 560.

The etch stop layer 570 may be disposed on the second interlayer insulating layer 540. The third interlayer insulating layer 580 may be disposed on the etch stop layer 570. Each first via V51 may extend through the third interlayer insulating layer 580 and the etch stop layer 570 in the vertical direction DR3 so as to be connected to each of the first and second upper source/drain contacts UCA51 and UCA52. Each second via V52 may extend through the third interlayer insulating layer 580 and the etch stop layer 570 in the vertical direction DR3 so as to be connected to each of the first and second through-vias TV51 and TV52. The third via V53 may extend through the third interlayer insulating layer 580 and the etch stop layer 570 in the vertical direction DR3 so as to be connected to the gate contact CBS.

By way of summation and review, when such a multi-gate transistor uses a three-dimensional channel, it may be easy to scale the same. Further, the current control capability of the multi-gate transistor may be improved without increasing a gate length of the multi-gate transistor. In addition, the multi-gate transistor may effectively suppress SCE (short channel effect) in which potential of a channel region is affected by drain voltage.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device comprising:
a substrate;
an active pattern disposed on the substrate and extending in a first horizontal direction;
a gate electrode disposed on the active pattern and extending in a second horizontal direction different from the first horizontal direction;
a lower source/drain region disposed on the active pattern and on at least one side of the gate electrode;
an upper source/drain region spaced apart from the lower source/drain region in a vertical direction;
a lower source/drain contact disposed between the lower source/drain region and the upper source/drain region, and connected to the lower source/drain region;
an upper source/drain contact disposed on the upper source/drain region and connected to the upper source/drain region;
an interlayer insulating layer surrounding the upper source/drain region;
a through-via disposed on one of two opposing sidewalls in the second horizontal direction of the upper source/drain region and extending through the interlayer insulating layer in the vertical direction, the through-via being spaced apart from each of the upper source/drain region and the upper source/drain contact in the second horizontal direction, the through-via being connected to the lower source/drain contact; and
a dam structure disposed on both of the two opposing sidewalls in the second horizontal direction of the upper source/drain region, the dam structure being in contact with the upper source/drain region, and the dam structure being spaced apart from the through-via in the second horizontal direction.

2. The semiconductor device as claimed in claim 1, wherein the dam structure includes: a first portion in contact with a first sidewall of the upper source/drain region; and
a second portion in contact with a second sidewall of the upper source/drain region opposite to the first sidewall of the upper source/drain region in the second horizontal direction.

3. The semiconductor device as claimed in claim 2, wherein the second portion of the dam structure is spaced apart from the first portion of the dam structure in the second horizontal direction.

4. The semiconductor device as claimed in claim 1, wherein the dam structure overlaps the lower source/drain contact in the vertical direction.

5. The semiconductor device as claimed in claim 1, wherein the dam structure is spaced apart from the lower source/drain contact in the vertical direction.

6. The semiconductor device as claimed in claim 1, wherein the dam structure is in contact with both of the two opposing sidewalls in the second horizontal direction of the upper source/drain contact.

7. The semiconductor device as claimed in claim 6, wherein a thickness in the second horizontal direction of a portion of the dam structure in contact with the upper source/drain region is greater than a thickness in the second horizontal direction of another portion of the dam structure in contact with the upper source/drain contact.

8. The semiconductor device as claimed in claim 1, wherein a top surface of the dam structure is coplanar with a top surface of the interlayer insulating layer.

9. The semiconductor device as claimed in claim 1, wherein both of the two opposing sidewalls in the second horizontal direction of the upper source/drain contact non-contacts the interlayer insulating layer.

10. The semiconductor device as claimed in claim 1, wherein a width in the second horizontal direction of the upper source/drain contact is equal to a width in the second horizontal direction of the upper source/drain region.

11. The semiconductor device as claimed in claim 1, further comprising:
a plurality of lower nanosheets stacked on the active pattern to be spaced apart from each other in the vertical direction;
an isolation layer disposed on the plurality of lower nanosheets; and
a plurality of upper nanosheets stacked on the isolation layer to be spaced apart from each other in the vertical direction,
wherein the gate electrode surrounds each of the plurality of lower nanosheets, the isolation layer and the plurality of upper nanosheets.

12. The semiconductor device as claimed in claim 11, wherein each of both opposing sidewalls in the first horizontal direction of the lower source/drain contact is in contact with the isolation layer.

13. The semiconductor device as claimed in claim 1, wherein a top surface of the dam structure is lower than a top surface of the upper source/drain contact, and
wherein each of both opposing sidewalls in the second horizontal direction of a portion of the upper source/drain contact positioned on the top surface of the dam structure is in contact with the interlayer insulating layer.

14. A semiconductor device comprising:
a substrate;
an active pattern disposed on the substrate and extending in a first horizontal direction;
a gate electrode disposed on the active pattern and extending in a second horizontal direction different from the first horizontal direction;
a lower source/drain region disposed on the active pattern and on at least one side of the gate electrode;
an upper source/drain region spaced apart from the lower source/drain region in a vertical direction;
a lower source/drain contact disposed between the lower source/drain region and the upper source/drain region, and connected to the lower source/drain region;
a through-via spaced apart from the upper source/drain region in the second horizontal direction, and connected to the lower source/drain contact; and
a dam structure disposed on each of both opposing sidewalls in the second horizontal direction of the upper source/drain region, the dam structure is in contact with the upper source/drain region, the dam structure is spaced apart from the through-via in the second horizontal direction, the dam structure overlaps the lower source/drain contact in the vertical direction,
wherein the dam structure includes:
a first portion in contact with a first sidewall of the upper source/drain region; and
a second portion in contact with a second sidewall of the upper source/drain region opposite to the first sidewall of the upper source/drain region in the second horizontal direction, the second portion is spaced apart from the first portion in the second horizontal direction.

15. The semiconductor device as claimed in claim 14, wherein the dam structure is spaced apart from the lower source/drain contact in the vertical direction.

16. The semiconductor device as claimed in claim 14, further comprising an upper source/drain contact disposed on the upper source/drain region and connected to the upper source/drain region, the upper source/drain contact is disposed between the first portion of the dam structure and the second portion of the dam structure.

17. The semiconductor device as claimed in claim 16, wherein the upper source/drain contact is in contact with each of the first portion of the dam structure and the second portion of the dam structure.

18. The semiconductor device as claimed in claim 14, wherein a top surface of the dam structure is coplanar with a top surface of the through-via.

19. The semiconductor device as claimed in claim 14, further comprising:
a plurality of lower nanosheets stacked on the active pattern to be spaced apart from each other in the vertical direction;
an isolation layer disposed on the plurality of lower nanosheets, the isolation layer is in contact with each of both opposing sidewalls in the first horizontal direction of the lower source/drain contact; and
a plurality of upper nanosheets stacked on the isolation layer to be spaced apart from each other in the vertical direction,
wherein the gate electrode surrounds each of the plurality of lower nanosheets, the isolation layer and the plurality of upper nanosheets.

20. A semiconductor device comprising:
a substrate;
an active pattern disposed on the substrate and extending in a first horizontal direction;
a plurality of lower nanosheets stacked on the active pattern to be spaced apart from each other in a vertical direction;
an isolation layer disposed on the plurality of lower nanosheets;
a plurality of upper nanosheets stacked on the isolation layer to be spaced apart from each other in the vertical direction;
a gate electrode disposed on the active pattern and extending in a second horizontal direction different from the first horizontal direction, the gate electrode surrounds each of the plurality of lower nanosheets, the isolation layer and the plurality of upper nanosheets;
a lower source/drain region disposed on the active pattern and on at least one side of each of the plurality of lower nanosheets;
an upper source/drain region disposed on the lower source/drain region and on at least one side of each of the plurality of upper nanosheets;
a lower source/drain contact disposed between the lower source/drain region and the upper source/drain region, and connected to the lower source/drain region;
an upper source/drain contact disposed on the upper source/drain region and connected to the upper source/drain region;
an interlayer insulating layer surrounding the upper source/drain region;
a through-via disposed on one of both opposing sidewalls in the second horizontal direction of the upper source/drain region and extending through the interlayer insulating layer in the vertical direction, the through-via being spaced apart from each of the upper source/drain region and the upper source/drain contact in the second horizontal direction, the through-via being connected to the lower source/drain contact; and
a dam structure disposed on both of two opposing sidewalls in the second horizontal direction of the upper source/drain region, the dam structure is in contact with each of the upper source/drain region and the upper source/drain contact, the dam structure is spaced apart from the through-via in the second horizontal direction, the dam structure overlaps the lower source/drain contact in the vertical direction,
wherein the dam structure comprises:
a first portion in contact with a first sidewall of the upper source/drain region; and
a second portion in contact with a second sidewall of the upper source/drain region opposite to the first sidewall of the upper source/drain region in the second horizontal direction, the second portion being spaced apart from the first portion in the second horizontal direction.
